(19) United States
(12) Patent Application Publication
(10) Pub. No.: US 2025/0126975 A1
(43) Pub. Date: Apr. 17, 2025

(54) DISPLAY DEVICE AND METHOD FOR MANUFACTURING DISPLAY DEVICE

(71) Applicant: SHARP KABUSHIKI KAISHA, Sakai City, Osaka (JP)

(72) Inventors: YASUSHI ASAOKA, Sakai City, Osaka (JP); Takahiro ADACHI, Sakai City, Osaka (JP); Yuma YAGUCHI, Sakai City, Osaka (JP)

(21) Appl. No.: 18/568,201

(22) PCT Filed: Aug. 6, 2021
(86) PCT No.: PCT/JP2021/029247

§ 371 Date: Dec. 7, 2023

(51) Int. Cl. H10K 59/122; B82Y 20/00; B82Y 40/00; H10K 50/115; H10K 59/12

(52) U.S. Cl. CPC H10K 59/122; H10K 50/115; H10K 59/1201; B82Y 20/00; B82Y 40/00

(57) ABSTRACT

The display device includes a light-emitting layer. The light-emitting layer includes light-emitting regions that have different predetermined luminescent colors and a non-light-emitting region that is different from the light-emitting regions and is formed in a region including an outer edge of the light-emitting layer. The non-light-emitting region includes a first outer edge region containing a first outer edge material different from a main luminescent material constituting the light-emitting region, at an outer edge of the light-emitting layer.

### TECHNICAL FIELD

The disclosure relates to a display device and a method for manufacturing the display device.

### BACKGROUND ART

PTL 1 discloses a display device including a light-emitting layer and a method for manufacturing the display device.

### CITATION LIST

### Patent Literature

PTL 1: US 2021/0066645 A

### SUMMARY

### Technical Problem

In PTL 1, a light-emitting layer is formed not only in a light-emitting region but also in part of a region on a bank that is a non-light-emitting region. In this case, part of the non-light-emitting region may emit light, causing color blurring, which may impair color development of a display device. Further, in order to increase pixel density, light-emitting layers, charge transport layers, and charge injection layers may be formed in contact with each other between a plurality of adjacent subpixels. Alternatively, in order to simplify a manufacturing process, a charge transport layer or a charge injection layer may be formed in common between a plurality of adjacent subpixels. In these cases, PL emission due to light leaking from the adjacent subpixel causes color mixing or the like, leading to poor color development or a decrease in resolution of the display device.

### Solution to Problem

In order to solve the above problems, a display device according to one aspect of the present disclosure includes a light-emitting layer, in which the light-emitting layer includes a light-emitting region configured to emit light of a predetermined color and a non-light-emitting region different from the light-emitting region and formed in a region including an outer edge of the light-emitting layer, and the non-light-emitting region includes a first outer edge region containing a first outer edge material different from a main luminescent material constituting the light-emitting region at the outer edge of the light-emitting layer.

In order to solve the above problems, a method for manufacturing a display device according to one aspect of the present disclosure includes depositing a first main luminescent material layer containing a first main luminescent material, depositing a first resist layer on the first main luminescent material layer, exposing the first resist layer, removing a portion of the first resist layer by developing the first resist layer, etching a portion of the first main luminescent material layer from a surface on a side of the first resist layer, forming a first outer edge region adjacent to at least one side surface of the first main luminescent material layer and containing a first outer edge material different from the first main luminescent material, and depositing a second main luminescent material layer containing a second main luminescent material having a different luminescent color from a luminescent color of the first main luminescent material.

### Advantageous Effects of Disclosure

Color blurring or color mixing in display devices can be reduced.

### BRIEF DESCRIPTION OF DRAWINGS

FIG. 1 is a schematic cross-sectional view of a display device according to a first embodiment, and partially enlarged views of the cross section.

FIG. 2 is a schematic plan view of the display device according to the first embodiment.

FIG. 3 is another partially enlarged view of the cross section of the display device according to the first embodiment.

FIG. 4 is a partially enlarged view of the cross section of the display device according to a modified example.

FIG. 5 is a flowchart illustrating a method for manufacturing the display device according to the first embodiment.

FIG. 6 is cross-sectional views illustrating steps in a manufacturing process for the display device according to the first embodiment.

FIG. 7 is cross-sectional views illustrating other steps in the manufacturing process for the display device according to the first embodiment.

FIG. 8 is cross-sectional views illustrating other steps in the manufacturing process for the display device according to the first embodiment.

FIG. 9 is cross-sectional views illustrating other steps in the manufacturing process for the display device according to the first embodiment.

FIG. 10 is partially enlarged views of the cross-sectional views illustrating the steps in the manufacturing process for the display device according to the first embodiment.

FIG. 11 is plan views illustrating steps in the manufacturing process for the display device according to the first embodiment.

FIG. 12 is plan views illustrating other steps in the manufacturing process for the display device according to the first embodiment.

FIG. 13 is a flowchart illustrating a method for manufacturing a display device according to a second embodiment.

FIG. 14 is cross-sectional views illustrating steps in a manufacturing process for the display device according to the second embodiment.

FIG. 15 is cross-sectional views illustrating other steps in the manufacturing process for the display device according to the second embodiment.

FIG. 16 is cross-sectional views illustrating other steps in the manufacturing process for the display device according to the second embodiment.

FIG. 17 is plan views illustrating steps in the manufacturing process for the display device according to the second embodiment.

FIG. 18 is a flowchart illustrating a method for manufacturing a display device according to a third embodiment.

FIG. 19 is plan views illustrating steps in a manufacturing process for the display device according to the third embodiment.

FIG. 20 is a schematic cross-sectional view of a display device according to a fourth embodiment.

FIG. 21 is a flowchart illustrating a method for manufacturing the display device according to the fourth embodiment.

FIG. 22 is a schematic cross-sectional view of a display device according to a fifth embodiment.

FIG. 23 is a flowchart illustrating a method for manufacturing the display device according to the fifth embodiment.

FIG. 24 is cross-sectional views illustrating steps in a manufacturing process for the display device according to the fifth embodiment.

FIG. 25 is cross-sectional views illustrating other steps in the manufacturing process for the display device according to the fifth embodiment.

FIG. 26 is a schematic cross-sectional view of a display device according to a sixth embodiment.

### DESCRIPTION OF EMBODIMENTS

### First Embodiment

### Outline of Display Device

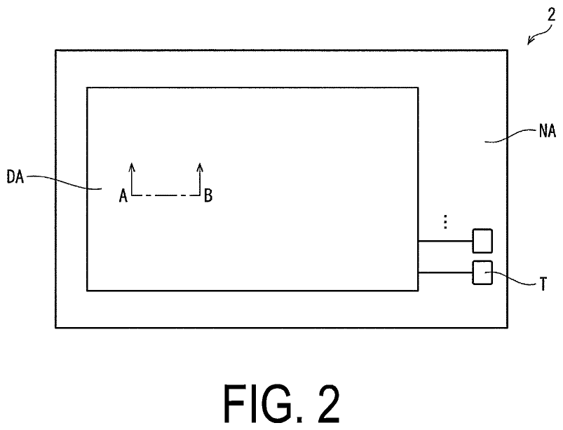

FIG. 2 is a plan view of a display device 2 according to the present embodiment. As illustrated in FIG. 2, the display device 2 according to the present embodiment includes a display region DA in which light emitted from each subpixel, which will be described later, is extracted for display, and a frame region NA that surrounds the display region DA. In the frame region NA, terminals T are formed to which signals for driving light-emitting elements of the display device 2 are respectively input.

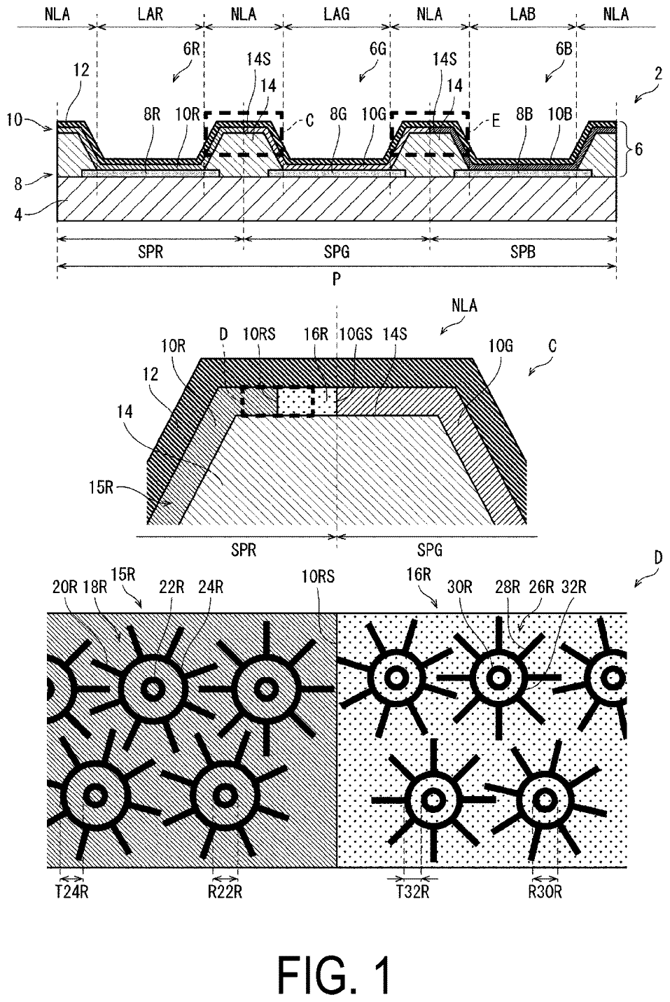

FIG. 1 is a schematic cross-sectional view of the display device 2 according to the present embodiment, and partially enlarged views of the cross section. The schematic cross-sectional view of the display device 2 illustrated in FIG. 1 is a cross-sectional view taken along line A-B in FIG. 2.

At a position overlapping the display region DA in a plan view, the display device 2 according to the present embodiment includes a plurality of pixels. Further, each pixel includes a plurality of subpixels. In the schematic cross-sectional view of the display device 2 illustrated in FIG. 1, a pixel P among the plurality of pixels included in the display device 2 is illustrated. In particular, the pixel P includes a red subpixel SPR, a green subpixel SPG, and a blue subpixel SPB.

As illustrated in FIG. 1, the display device 2 according to the present embodiment includes a light-emitting element layer 6 on a substrate 4. In particular, the display device 2 has a structure in which layers constituting the light-emitting element layer 6 are layered on the substrate 4, on which thin film transistors (TFTs; not illustrated) are formed. Note that, in this specification, a direction from a light-emitting layer 10 to a pixel electrode 8 in the light-emitting element layer 6 described later is described as a “downward direction”, and a direction from the light-emitting layer 10 to a common electrode 12 is described as an “upward direction”.

### Outline of Light-Emitting Element

The light-emitting element layer 6 includes, in order from a substrate 4 side, the pixel electrode 8 as a first electrode, the light-emitting layer 10 as a light-emitting member, and the common electrode 12 as a second electrode. In other words, the light-emitting element layer 6 includes the light-emitting layer 10 between the pixel electrode 8 and the common electrode 12. The pixel electrode 8 of the light-emitting element layer 6, which is formed on the substrate 4, is formed in an island shape for each subpixel described above, and electrically connected to each of the TFTs on the substrate 4. Note that, in the display device 2, a sealing layer (not illustrated) may be provided on the light-emitting element layer 6 to seal the light-emitting element layer 6.

In the present embodiment, the light-emitting element layer 6 includes a plurality of light-emitting elements and, in particular, includes one light-emitting element for each subpixel. In the present embodiment, for example, the light-emitting element layer 6 includes, as the light-emitting elements, a red light-emitting element 6R in the red subpixel SPR, a green light-emitting element 6G in the green subpixel SPG, and a blue light-emitting element 6B in the blue subpixel SPB. Hereinafter, in this specification, unless otherwise specified, “light-emitting element” refers to any one of the red light-emitting element 6R, the green light-emitting element 6G, and the blue light-emitting element 6B included in the light-emitting element layer 6.

Herein, the pixel electrode 8 and the light-emitting layer 10 are each individually formed on a subpixel-by-subpixel basis. In particular, in the present embodiment, the pixel electrode 8 includes a pixel electrode 8R for the red light-emitting element 6R, a pixel electrode 8G for the green light-emitting element 6G, and a pixel electrode 8B for the blue light-emitting element 6B. The light-emitting layer 10 includes a red light-emitting region LAR for the red light-emitting element 6R, a green light-emitting region LAG for the green light-emitting element 6G, and a blue light-emitting region LAB for the blue light-emitting element 6B. On the other hand, the common electrode 12 is formed in common for the plurality of subpixels.

Thus, in the present embodiment, the red light-emitting element 6R includes the pixel electrode 8R, the red light-emitting region LAR, and the common electrode 12. The green light-emitting element 6G includes the pixel electrode 8G, the green light-emitting region LAG, and the common electrode 12. The blue light-emitting element 6B includes the pixel electrode 8B, the blue light-emitting region LAB, and the common electrode 12.

In the present embodiment, the red light-emitting region LAR is a red EL emission region and includes a red light-emitting layer 10R that emits red light. The green light-emitting region LAG is a green EL emission region and includes a green light-emitting layer 10G that emits green light. The blue light-emitting region LAB is a blue EL emission region and includes a blue light-emitting layer 10B that emits blue light. In other words, the red light-emitting element 6R, the green light-emitting element 6G, and the blue light-emitting element 6B are light-emitting elements that respectively emit red light, green light, and blue light. In other words, the light-emitting layer 10 includes the red light-emitting region LAR that emits red light, the green light-emitting region LAG that emits green light, and the blue light-emitting region LAB that emits blue light, as a plurality of types of EL emission regions having different luminescent colors from each other.

Here, the blue light refers to, for example, light having an emission center wavelength in a wavelength band of equal to or greater than 400 nm and equal to or less than 500 nm. The green light refers to, for example, light having an emission center wavelength in a wavelength band of greater than 500 nm and equal to or less than 600 nm. The red light refers to, for example, light having an emission center wavelength in a wavelength band of greater than 600 nm and equal to or less than 780 nm.

Note that the light-emitting element layer 6 according to the present embodiment is not limited to the above configuration and may further include an additional layer as a function layer between the pixel electrode 8 and the common electrode 12. For example, the light-emitting element layer 6 may further include at least one of a charge injection layer and a charge transport layer in addition to the light-emitting layer 10 as a function layer between the pixel electrode 8 and the light-emitting layer 10. The light-emitting element layer 6 may further include at least one of a charge injection layer and a charge transport layer between the light-emitting layer 10 and the common electrode 12.

When the light-emitting element layer 6 includes any one of a hole injection layer, a hole transport layer, an electron transport layer, or an electron injection layer as a function layer as a charge transport layer, the charge transport layer may contain quantum dots. A quantum dot includes, for example, a core and a shell covering the core, but the quantum dot contained in the charge transport layer may have a structure of only the core. The charge transport layer may include nanoparticle semiconductors containing ZnO, CuO, or the like as quantum dots. Furthermore, ligands may be coordinated to the quantum dots contained in the charge transport layer. In this specification, the term “ligand” refers to a molecule having a coordinating functional group capable of coordination bonding with the outermost surface of the quantum dot. Examples of the coordinating functional group include a thiol group, an amino group, a carboxyl group, a phosphonic group, a phosphine group, and a phosphine oxide group.

The pixel electrode 8 and the common electrode 12 contain conductive materials and are electrically connected to the light-emitting layer 10. Of the pixel electrode 8 and the common electrode 12, the electrode closer to a display surface of the display device 2 is a semitransparent electrode.

The pixel electrode 8 has, for example, a configuration in which indium tin oxide (ITO) is layered on an Ag—Pd—Cu alloy. The pixel electrode 8 having the above configuration is, for example, a reflective electrode that reflects light emitted from the light-emitting layer 10. Thus, light emitted from the light-emitting layer 10 that is directed downward is reflected by the pixel electrode 8.

On the other hand, the common electrode 12 is made of, for example, a semitransparent Mg—Ag alloy. That is, the common electrode 12 is a transmissive electrode that transmits light emitted from the light-emitting layer 10. Therefore, light emitted from the light-emitting layer 10 that is directed upward is transmitted through the common electrode 12. Thus, the display device 2 can emit light emitted from the light-emitting layer 10 upward.

As described above, in the display device 2, both the light emitted upward and the light emitted downward from the light-emitting layer 10 can be directed toward the common electrode 12 (upward). That is, the light-emitting device 2 is configured as a top-emitting type display device.

In the present embodiment, the common electrode 12, which is a semitransparent electrode, partially reflects light emitted from the light-emitting layer 10. In this case, an optical cavity emitted from the light-emitting layer 10 may be formed between the pixel electrode 8, which is a reflective electrode, and the common electrode 12, which is a semitransparent electrode. By forming the cavity between the pixel electrode 8 and the common electrode 12, a half width of emission spectrum of the light emitted from the light-emitting layer 10 can be narrowed to widen a display color gamut or brightness in a front direction can be increased to improve the color gamut and brightness of the display device.

Note that the configuration of the pixel electrode 8 and the common electrode 12 described above is an example and may be another configuration. For example, the electrode closer to the display surface of the display device 2 may be the pixel electrode 8. In this case, the pixel electrode 8 may be a semitransparent electrode, and the common electrode 12 may be a reflective electrode. Thus, in the display device 2, both the light emitted upward and the light emitted downward from the light-emitting layer 10 can be directed toward the pixel electrode 8 (downward). That is, the light-emitting device 2 may be configured as a bottom-emitting type display device.

The light-emitting layer 10 is a layer that emits light when recombination occurs between positive holes transported from the pixel electrode 8 and electrons transported from the common electrode 12. Details of materials and the like contained in the light-emitting layer 10 will be described below.

When the pixel electrode 8 is an anode electrode, the common electrode 12 is a cathode electrode. When the pixel electrode 8 is a cathode electrode, the common electrode 12 is an anode electrode.

The display device 2 according to the present embodiment further includes a bank 14 on the substrate 4. The bank 14 is formed at positions straddling boundaries between subpixels adjacent to each other in a plan view. In particular, the pixel electrode 8 is separated by the bank 14 into the pixel electrode 8R, the pixel electrode 8G, and the pixel electrode 8B. Note that, as illustrated in FIG. 1, the bank 14 may be formed at positions covering peripheral edges of the pixel electrodes of the pixel electrode 8, respectively.

In the present embodiment, each portion of the bank 14 has an upper face 14S on a common electrode 12 side. Here, in the present embodiment, each portion of the bank 14 is formed such that the upper face 14S straddles the boundary between the subpixels adjacent to each other. A region on the bank 14 is a non-light-emitting region NLA, which is a region not intended for EL emission. Thus, the bank 14 divides subpixels having different luminescent colors from each other.

### Outer Edge Region

A configuration of the light-emitting layer 10 on an outer surface of the bank 14 including the upper face 14S will be described with reference to a partially enlarged view of the cross section of the display device 2 illustrated in FIG. 1. A region C illustrated in FIG. 1 is a region located in the vicinity of the upper face 14S of the bank 14 at a position straddling the boundary between the red subpixel SPR and the green subpixel SPG in the schematic cross-sectional view of the display device 2 in FIG. 1. The region C illustrated in FIG. 1 is on the bank and is therefore the non-light-emitting region NLA.

At least one light-emitting layer in the display device 2 includes a main region and an outer edge region formed at an outer edge of the light-emitting layer. The main region is a region capable of mainly exhibiting a light-emitting function, which is a main function of the light-emitting layer. For example, the red light-emitting layer 10R is formed in a light-emitting region that mainly emits red light. The main region may also be formed in the non-light-emitting region NLA. The outer edge region is a region formed at the outer edge of the light-emitting layer and is made of an outer edge material that is a material different from a main luminescent material used for the main region.

On the outer surface of the bank 14 illustrated in the enlarged view of the region C in FIG. 1, the red light-emitting layer 10R and the green light-emitting layer 10G are formed. Here, the red light-emitting layer 10R includes a red main region 15R and a red first outer edge region 16R adjacent to a side surface 10RS of an edge on a green light-emitting layer 10G side. The red first outer edge region 16R is formed on the upper face 14S of the bank 14 and is in contact with a side surface 10GS of an edge of the green light-emitting layer 10G on a red light-emitting layer 10R side. Since the red first outer edge region 16R is formed on the upper face 14S of the bank 14, the red first outer edge region 16R is formed at a position overlapping the bank 14 in a plan view of the light-emitting layer 10.

### Main Luminescent Material and Outer Edge Material

The red main region 15R and the red first outer edge region 16R will be further described with reference to another partially enlarged view of the cross section of the display device 2 illustrated in FIG. 1. A region D illustrated in FIG. 1 is a region located in the vicinity of the side surface 10RS of the red main region 15R that is in contact with the red first outer edge region 16R in the region C.

As illustrated in the enlarged view of the region D in FIG. 1, the red light-emitting layer 10R contains, as a main luminescent material, a plurality of red quantum dots 18R and red main ligands 20R coordinated to each of the red quantum dots 18R. In the present embodiment, positive holes from the anode electrode and electrons from the cathode electrode are injected into the red quantum dots 18R to which the red main ligands 20R are coordinated, and the positive holes and the electrons generate excitons. Furthermore, the red quantum dots 18R to which the red main ligands 20R are coordinated emit red light due to recombination of the generated excitons.

Each of the red quantum dots 18R has, for example, a structure commonly called a core/shell type, including a core 22R and a shell 24R as a main shell surrounding the core 22R. Recombination of an electron and a positive hole and generation of red light in the red quantum dot 18R occur mainly in the core 22R. The shell 24R has functions of suppressing generation of defects, dangling bonds, or the like in the core 22R and reducing recombination of an electron and a positive hole through a deactivation process. In this case, the red main ligands 20R are coordinated to the outer surface of the shell 24R.

In the red quantum dot 18R, materials of the core 22R and the shell 24R may include materials used for the core material and the shell material of a quantum dot having a known core/shell, respectively. In the present embodiment, the core 22R has a diameter R22R and the shell 24R has a thickness T24R. The red main ligands 20R may contain a material used for known ligands that have a function of reducing aggregation in dispersion of the red quantum dots 18R. In addition, the material used for the known ligands, which is contained in the red main ligands 20R, may further have a function of suppressing generation of defects, dangling bonds, or the like on the shell surfaces and reducing recombination of electrons and positive holes through a deactivation process.

On the other hand, as illustrated in the enlarged view of the region D in FIG. 1, the red first outer edge region 16R contains, as a first outer edge material, a plurality of red first quantum dots 26R and red first outer edge ligands 28R that are coordinated to each of the red first quantum dots 26R. Each of the red first quantum dots 26R has, for example, a structure commonly called a core/shell type, including a core 30R and a shell 32R as a first shell surrounding the core 30R. In the present embodiment, the core 30R has a diameter R30R and the shell 32R has a thickness T32R.

In the present embodiment, the main luminescent material of the red main region 15R and the first outer edge material of the red first outer edge region 16R are different materials from each other. For example, the red main ligands 20R and the red first outer edge ligands 28R are different ligands from each other. For example, the red main ligands 20R are soluble in non-polar solvents and the red first outer edge ligands 28R are soluble in polar solvents such as water. In this case, the red quantum dots 18R coordinated with the red main ligands 20R are insoluble in polar solvents, and the red first quantum dots 26R coordinated with the red first outer edge ligands 28R are soluble in polar solvents.

Note that the main luminescent material in the red main region 15R and the first outer edge material in the red first outer edge region 16R may be at least partially different from each other. Here, “two materials are different” does not mean only that the ligands are different. For example, “two materials are different” may mean at least one of different constituent materials of quantum dots, different densities of quantum dots, different densities of ligands, different thicknesses of shells of quantum dots, presence or absence of oxidized quantum dots, and the like. In addition, when the “two materials” include organic materials, “two materials are different” may mean that the organic materials are different.

The first outer edge material contained in the red first outer edge region 16R is a material having a shorter luminous lifetime or lower luminous efficiency relative to the density of injected electrons and positive holes than the main luminescent material contained in the red main region 15R. Furthermore, the first outer edge material contained in the red first outer edge region 16R may be a material that does not emit light. In other words, the first outer edge material contained in the red first outer edge region 16R may be a material having a luminous lifetime of 0.

### Another Example of Outer Edge Region

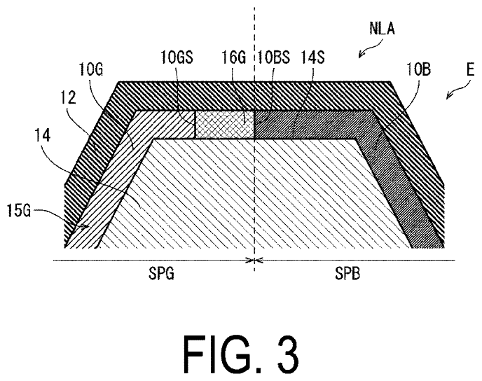

Another configuration of the light-emitting layer 10 on the outer surface of the bank 14 will be described with reference to another partially enlarged view of the cross section of the display device 2 illustrated in FIG. 3. A region E illustrated in FIG. 3 is a region located in the vicinity of the upper face 14S of the bank 14 at a position straddling the boundary between the green subpixel SPG and the blue subpixel SPB in the schematic cross-sectional view of the display device 2 in FIG. 1.

On the outer surface of the bank 14 illustrated in the enlarged view of the region E in FIG. 3, the green light-emitting layer 10G having a green first main region 15G and a green first outer edge region 16G and the blue light-emitting layer 10B are formed. Here, the green first outer edge region 16G is formed adjacent to a side surface 10GS of an edge of the green first main region 15G on a blue light-emitting layer 10B side. The green first outer edge region 16G is formed on the upper face 14S of the bank 14 and is in contact with a side surface 10BS of an edge of the blue light-emitting layer 10B on a green light-emitting layer 10G side.

The green first main region 15G contains a main luminescent material that emits green light. The green first main region 15G, for example, similar to the red main region 15R, may contain, as the main luminescent material, a plurality of green quantum dots that emit green light and main ligands that are coordinated to each of the green quantum dots.

The green first outer edge region 16G contains a first outer edge material different from the main luminescent material contained in the green first main region 15G. The green first outer edge region 16G, may contain, for example, as the first outer edge material, a plurality of green first quantum dots having lower luminous efficiency or a lower luminous lifetime than the green quantum dots contained in the green first main region 15G. Furthermore, the green first outer edge region 16G may contain green first outer edge ligands that are coordinated to each of the green first quantum dots and are different from the main ligands contained in the green first main region 15G.

### Effects of Display Device

The red light-emitting region LAR of the red light-emitting layer 10R includes the red main region 15R, which is a main region, containing the red quantum dots 18R, as the main luminescent material, to which the red main ligands 20R are coordinated. On the other hand, the non-light-emitting region NLA includes the red first outer edge region 16R adjacent to the side surface 10RS of the red main region 15R and containing the red first quantum dots 26R, which are the first outer edge material different from the main luminescent material, to which the red first outer edge ligands 28R are coordinated. The outer edge material is a material that has lower luminous efficiency than the main luminescent material or does not emit light.

When the light-emitting layer is formed not only in the main region but also in the non-light-emitting region, electrons or positive holes injected into the main region may flow to the non-light-emitting region where EL emission is not intended. Thus, part of the non-light-emitting region may emit light, causing color blurring in the subpixel. When at least a portion of the light-emitting layer is adjacent to the light-emitting layer of an adjacent subpixel, color mixing may occur between the subpixels due to PL emission caused by light leaked from the adjacent subpixel. Such color blurring or color mixing causes poor color development of the display device.

In the red light-emitting layer 10R, by forming the outer edge region, which has the lower luminous efficiency than the main region or does not emit light, as the non-light-emitting region located at the outer edge of the red light-emitting layer 10R, influence of color blurring of the subpixel can be suppressed. In addition, since the outer edge region suppresses light emission in the non-light-emitting region, light that may leak to the adjacent subpixel is reduced, so that influence of color mixing between subpixels is suppressed.

The light-emitting layer may come into contact with moisture during a manufacturing process or due to partial breakage of the display device. When moisture is in contact with the light-emitting layer, luminous efficiency or a luminous lifetime of the light-emitting layer may be reduced due to penetration of moisture or the like into the light-emitting layer. In the red light-emitting layer 10R, the red first outer edge region 16R may protect the red light-emitting region LAR from moisture by suppressing penetration of moisture or the like into the red main region 15R, thereby suppressing deterioration of the function of the red light-emitting layer 10R and preventing deterioration of luminous efficiency or a luminous lifetime. A case in which the light-emitting region can be protected from penetration of moisture or the like will be described later.

In the present embodiment, the blue subpixel SPB may include only the blue light-emitting region LAB. In other words, in the present embodiment, only in the blue subpixel SPB, the light-emitting layer 10 may include only the main region. In other words, the light-emitting layer 10 of the display device 2 according to the present embodiment only need to have a main region and an outer edge region formed at an outer edge of the main region in at least one subpixel among the plurality of subpixels.

In the case described above, the display device 2 includes three types of subpixels having different luminescent colors: the red subpixel SPR, the green subpixel SPG, and the blue subpixel SPB. Further, among the subpixels of the display device 2, the main region and the first outer edge region are located in each of two types of subpixels: the red subpixel SPR and the green subpixel SPG.

Note that the display device 2 may further include other subpixels including a yellow subpixel that emits yellow light in addition to the three types of subpixels: the red subpixel SPR, the green subpixel SPG, and the blue subpixel SPB. For example, when the display device 2 includes n types of subpixels having different luminescent colors, where n is a natural number of 2 or more, the main region and the first outer edge region may be located only in each of the (n−1) types of subpixels.

With the above configuration, the display device 2 can include a large number of subpixels in which the light-emitting regions are protected by the first outer edge regions. When the main region has higher luminous efficiency or a longer luminous lifetime than the first outer edge region in the same subpixels, by providing the light-emitting regions including only the main region, the light-emitting layer 10 increases areas having high luminous efficiency or a long luminous lifetime in these light-emitting regions.

### Details of Main Luminescent Material and Outer Edge Material

In the present embodiment, the red first outer edge region 16R and the green first outer edge region 16G are formed at positions overlapping the bank 14 in a plan view of the light-emitting layer 10. Although a region on the bank 14 is the non-light-emitting region NLA, with the above configuration, in the red first outer edge region 16R and the green first outer edge region 16G, injection and recombination of electric charges from the pixel electrode 8 and electric charges from the common electrode 12 are more difficult to occur. Therefore, compared to the red light-emitting layer 10R and the green light-emitting layer 10G, light emission from each of the red first outer edge region 16R and the green first outer edge region 16G is less likely to be obtained, thereby suppressing occurrence of color blurring, color mixing, or the like.

In the present embodiment, for example, a density of the red first outer edge ligands 28R in the red first outer edge region 16R may be lower than a density of the red main ligands 20R in the red main region 15R. In this case, surface defects of the quantum dots increase in the red first outer edge region 16R, making it more difficult to emit light than in the red main region 15R, thereby suppressing occurrence of color blurring, color mixing, or the like. The red first quantum dots 26R in the red first outer edge region 16R are in a more aggregated state than the red quantum dots 18R in the red main region 15R, so infiltration of oxygen or moisture from the side surface of the light-emitting layer 10R is further suppressed. Thus, occurrence of defects in the red light-emitting layer 10R can be reduced. Therefore, with the above configuration, in the red light-emitting region LAR of the red light-emitting layer 10R, luminous efficiency can be maintained in a high state or a luminous lifetime can be maintained in a long state.

Further, for example, the thickness T32R of the shell 32R may be thinner than the thickness T24R of the shell 24R. Also in this case, in the red first outer edge region 16R, surface defect density of the quantum dots increases or electron or positive hole confinement effect in the core 30R decreases. Thus, light emission due to the recombination of electrons and positive holes in the quantum dots is less likely to occur, making it more difficult to emit light than in the red main region 15R, thereby suppressing occurrence of color blurring, color mixing, or the like. The red first quantum dots 26R in the red first outer edge region 16R have a smaller particle size than the red quantum dots 18R in the red main region 15R, so the quantum dots are more densely filled. Thus, the infiltration of oxygen or moisture from the side surface of the light-emitting layer 10R is further suppressed, thereby reducing the occurrence of defects in the red light-emitting layer 10R. Therefore, with the above configuration, luminous efficiency or a luminous lifetime in the red main region 15R can be improved more efficiently than luminous efficiency or a luminous lifetime in the red first outer edge region 16R.

In addition, for example, the material of the red first quantum dots 26R may be an oxide of the material of the red quantum dots 18R. In general, oxidation of quantum dots tends to reduce luminous efficiency or a luminous lifetime of the quantum dots. Therefore, with the above configuration, charge injection and recombination of charges are less likely to occur in the red first outer edge region 16R, making it difficult to emit light than in the red main region 15R, thereby suppressing occurrence of color blurring, color mixing, or the like. Thus, luminous efficiency of the red light-emitting layer 10R in the red light-emitting region LAR can be maintained in a high state, or the luminous lifetime can be maintained in a long state.

As described above, in the present embodiment, the occurrence of color blurring, color mixing, or the like can be suppressed in at least one subpixel. In some examples, luminous efficiency or a luminous lifetime of the light-emitting region may be improved by preventing infiltration of moisture in at least one light-emitting region of the light-emitting layer 10.

In the present embodiment, the red main ligands 20R in the red main region 15R and the red first outer edge ligands 28R in the red first outer edge region 16R may be different ligands from each other. In this case, the display device 2 according to the present embodiment can more efficiently provide the red first outer edge region 16R with a different function from that of the red main region 15R due to a difference in the ligands contained therein.

For example, in the present embodiment, the red quantum dots 18R coordinated with the red main ligands 20R may be soluble in non-polar solvents, and the red first quantum dots 26R coordinated with the red first outer edge ligands 28R may be soluble in polar solvents. When the red first quantum dots 26R coordinated with the red first outer edge ligands 28R are soluble in polar solvents, the red first quantum dots 26R can retain at least some of moisture that has penetrated to the red light-emitting layer 10R from the red first outer edge region 16R side. Thus, when the red first quantum dots 26R coordinated with the red first outer edge ligands 28R are soluble in polar solvents, the red light-emitting layer 10R can prevent moisture from penetrating into the red main region 15R. Accordingly, penetration of moisture into the red main region 15R is reduced, thereby reducing deterioration of the main luminescent material of the red light-emitting layer 10R.

For example, when the red quantum dots 18R coordinated with the red main ligands 20R are soluble in non-polar solvents, the red main ligands 20R may be ligands for non-polar solvents containing at least one coordinating functional group selected from the group consisting of a thiol group, an amino group, a carboxyl group, a phosphonic group, a phosphine group, and a phosphine oxide group.

Examples of the ligands for non-polar solvents containing one thiol group as the coordinating functional group described above include ligands containing octadecanethiol, hexanedecanethiol, tetradecanethiol, dodecanethiol, decanethiol, and octanethiol as thiol-based ligands.

Examples of the ligands for non-polar solvents containing one amino group as the coordinating functional group described above include ligands containing oleylamine, stearylamine (octadecylamine), dodecylamine (laurylamine), decylamine, and octylamine as primary amine-based ligands.

Examples of the ligands for non-polar solvents containing one carboxyl group as the coordinating functional group described above include ligands containing oleic acid, stearic acid, palmitic acid, myristic acid, lauric (dodecanoic) acid, decanoic acid, and octanoic acid as fatty acid-based ligands.

Examples of the ligands for non-polar solvents containing one phosphonic group as the coordinating functional group described above include ligands containing hexadecylsulfonic acid as phosphonic acid-based ligands.

Examples of the ligands for non-polar solvents containing one phosphine group as the coordinating functional group described above include ligands containing trioctylphosphine, triphenylphosphine, and tributylphosphine as phosphine-based ligands.

Examples of the ligands for non-polar solvents containing one phosphine oxide group as the coordinating functional group described above include ligands containing trioctylphosphine oxide, triphenylphosphine oxide, and tributylphosphine oxide as phosphine oxide-based ligands.

When the red quantum dots 18R coordinated with the red main ligands 20R are soluble in non-polar solvents, the red first quantum dots 26R coordinated with the red first outer edge ligands 28R are soluble in polar solvents, for example. In this case, the red first outer edge ligands 28R may include at least one of the ligands for polar solvents selected from the group consisting of tetramethylammonium hydroxide (TMAH), tetrabutylammonium bromide (TBAB), 2-aminoethanethiol hydrochloride, 2-methaneaminoethanethiol hydrochloride, 2-ethanaminoethanethiol hydrochloric acid, 2-dimethylaminoethanethiol hydrochloride, 2-methylethylaminoethanethiol hydrochloride, and 2-diethylaminoethanethiol hydrochloride. The red first outer edge ligand 28R may also include inorganic ligands (e.g., S2-, Cl—, Br—, I—, F—, etc.) that can be dispersed in highly polar solvents.

On the other hand, the red quantum dots 18R coordinated with the red main ligands 20R may be soluble in polar solvents, and the red first quantum dots 26R coordinated with the red first outer edge ligands 28R may be soluble in non-polar solvents. In this case, the red main ligands 20R are ligands for the above polar solvents. In the case described above, the red first outer edge ligands 28R are ligands for the above non-polar solvents.

In the present embodiment, each of the red light-emitting layer 10R, the green light-emitting layer 10G, and the blue light-emitting layer 10B contains the inorganic quantum dot material as the main luminescent material has been described. However, not limited to this, in the present embodiment, each of the red light-emitting layer 10R, the green light-emitting layer 10G, and the blue light-emitting layer 10B may contain an organic luminescent material as the main luminescent material.

In this case, the red first outer edge region 16R and the green first outer edge region 16G may contain first organic materials that are altered products of organic luminescent materials contained in the red light-emitting layer 10R and the green light-emitting layer 10G, respectively. Note that the altered products of organic luminescent materials include a material obtained by substituting some elements of the organic luminescent material, an oxide of the organic luminescent material, and the like.

### Modified Example of Outer Edge Region

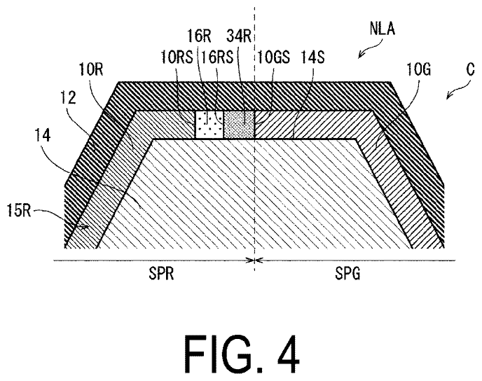

FIG. 4 is an enlarged cross-sectional view of the display device 2 according to a modified example of the present embodiment. The region C illustrated in FIG. 4 is a region corresponding to the region C illustrated in FIG. 1. The display device 2 according to this modified example is different from the display device 2 according to the present embodiment only in that the light-emitting layer 10 further includes a red second outer edge region 34R as a second outer edge region in the red subpixel SPR.

The red second outer edge region 34R is formed adjacent to a side surface 16RS of an edge of the red first outer edge region 16R on the green light-emitting layer 10G side. The red second outer edge region 34R is formed on the upper face 14S of the bank 14 and is in contact with the side surface 10GS of the edge of the green light-emitting layer 10G on the red light-emitting layer 10R side. Since the red second outer edge region 34R is formed on the upper face 14S of the bank 14, the red second outer edge region 34R is formed at a position overlapping the bank 14 in a plan view of the light-emitting layer 10.

The red second outer edge region 34R includes a second outer edge material that is different from both the main luminescent material of the red light-emitting layer 10R and the first outer edge material of the red first outer edge region 16R. The red second outer edge region 34R may contain, for example, as the second outer edge material, a plurality of second quantum dots having lower luminous efficiency or a shorter luminous lifetime than the red first quantum dots 26R. Furthermore, the red second outer edge region 34R may contain second ligands that are coordinated to each of the second quantum dots and are different from both the red main ligands 20R and the red first outer edge ligands 28R. Alternatively, the red second outer edge region 34R may contain the red first outer edge ligands 28R, and a density of the red first outer edge ligands 28R in the red second outer edge region 34R may be higher than the density of the red first outer edge ligands 28R in the red first outer edge region 16R.

The display device 2 according to this modified example further includes the red second outer edge region 34R adjacent to the outer edge of the red first outer edge region 16R in the non-light-emitting region NLA. Thus, the display device 2 according to this modified example can provide an effect of protecting the red main region 15R by both the red first outer edge region 16R and the red second outer edge region 34R, thereby more efficiently protecting the red light-emitting layer 10R.

Furthermore, the second outer edge material contained in the red second outer edge region 34R is at least partially different from the first outer edge material contained in the red first outer edge region 16R. Thus, the display device 2 according to this modified example can more simply provide the red second outer edge region 34R with a function different from the function of the red first outer edge region 16R due to a difference in the outer edge material contained therein.

### Overview of Method for Manufacturing Display Device

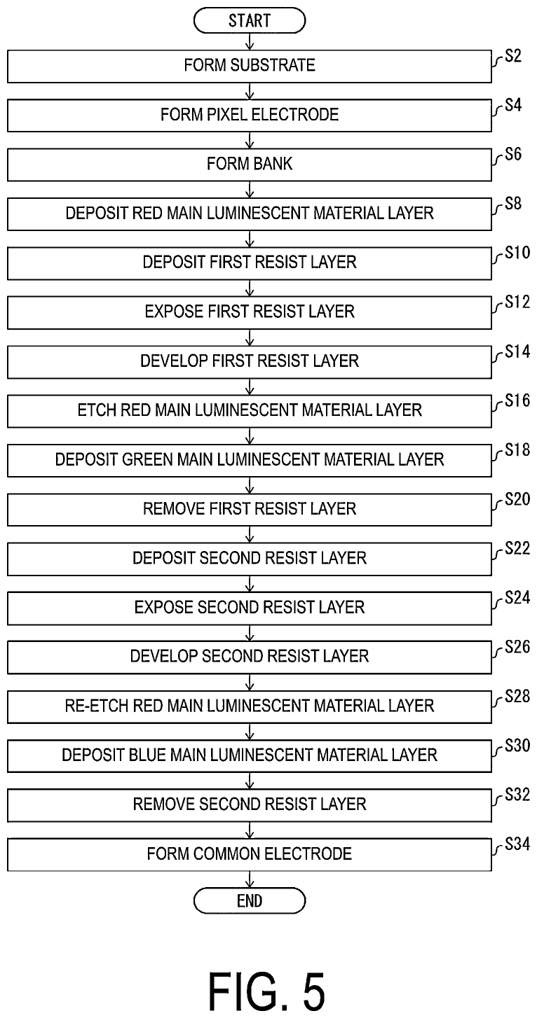

A method for manufacturing the display device 2 according to the present embodiment will be described with reference to FIG. 5. FIG. 5 is a flowchart for describing the method for manufacturing the display device 2 according to the present embodiment. The display device 2 according to the modified example described above can be manufactured using the same method as that for manufacturing the display device 2 according to the present embodiment, unless otherwise specified.

In the method for manufacturing the display device 2 according to the present embodiment, first, the substrate 4 is formed (step S2). The substrate 4 may be formed by forming TFTs on a glass substrate to match positions where the respective subpixels of the display device 2 are formed.

Subsequently, the pixel electrode 8 is formed (step S4). The pixel electrode 8 may be formed by, for example, depositing a conductive material in common to the subpixels by sputtering or the like as described above, and then patterning thin films of the conductive material on a subpixel-by-subpixel basis.

Subsequently, the bank 14 is formed (step S6). The bank 14 may be formed, for example, by applying a resin material containing a photosensitive material on the substrate 4 and the pixel electrode 8, and then patterning the resin material by photolithography.

### Deposition and Etching of Main Luminescent Material Layer

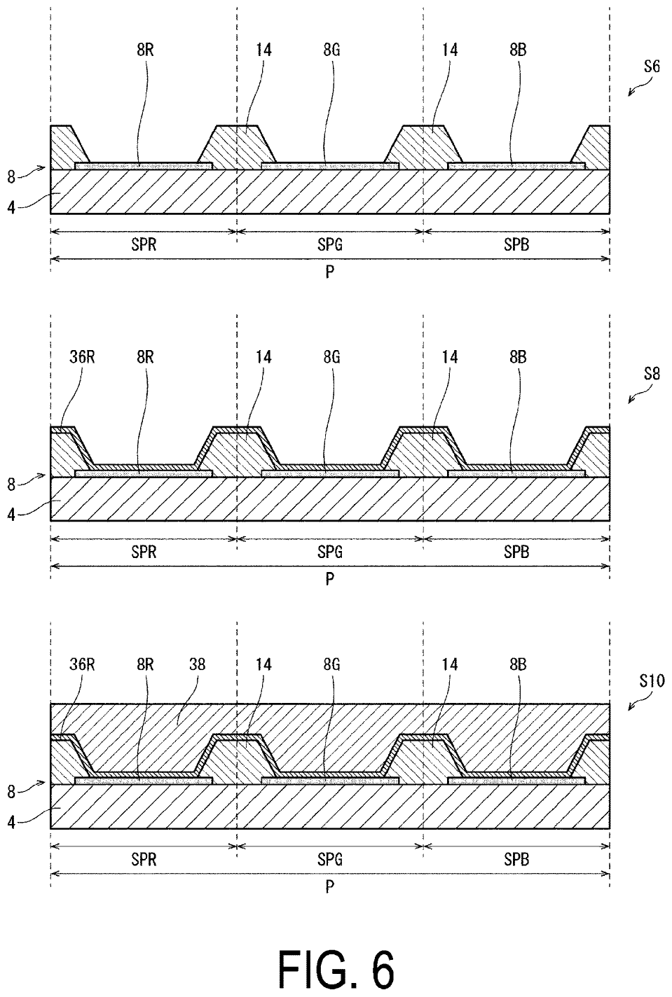

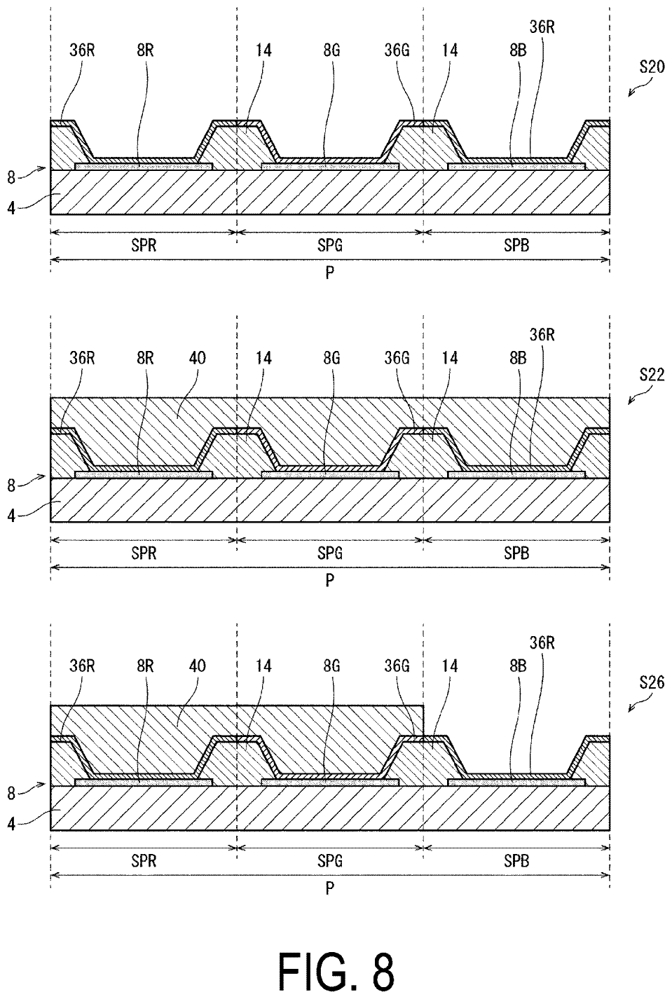

Step S6 and subsequent steps in the method for manufacturing the display device 2 according to the present embodiment will be described in more detail with reference to FIG. 6 to FIG. 9. FIG. 6 to FIG. 9 are cross-sectional views illustrating steps of the display device 2 in some steps of the method for manufacturing the display device 2 according to the present embodiment. Note that cross-sectional views illustrating steps in this specification, including FIG. 6 to FIG. 9, are illustrated at a position corresponding to the cross section of the display device 2 illustrated in FIG. 1, unless otherwise specified.

By performing the steps up to step S6, a structure in which the pixel electrode 8 and the bank 14 are formed is formed on the substrate 4, as illustrated in step S6 in FIG. 6. The pixel electrodes 8 include the pixel electrode 8R in the red subpixel SPR, the pixel electrode 8G in the green subpixel SPG, and the pixel electrode 8B in the blue subpixel SPB, which are formed by patterning a conductive material on a subpixel-by-subpixel basis, as island-shaped pixel electrodes. The bank 14 is formed at positions covering the boundaries of the subpixels and the peripheral edge portions of the pixel electrodes of the pixel electrode 8.

In the method for manufacturing the display device 2 according to the present embodiment, following the formation of the bank 14, a red main luminescent material layer 36R containing the main luminescent material contained in the red light-emitting layer 10R as the first main luminescent material is deposited as the first main luminescent material layer (step S8). Step S8 is a first main luminescent material deposition step of depositing the first main luminescent material layer containing the first main luminescent material. The red main luminescent material layer 36R is formed in common to a plurality of subpixels. The red main luminescent material layer 36R contains, for example, the red quantum dots 18R as first main quantum dots and the main ligands 20R as first main ligands. Deposition of the red main luminescent material layer 36R may be performed by, for example, coating, vapor deposition, or the like.

Subsequently, a first resist layer 38 is deposited on the red main luminescent material layer 36R (step S10). Step S10 is a first resist layer deposition step of depositing the first resist layer on the first main luminescent material layer. The first resist layer 38 according to the present embodiment contains a photosensitive resin material. In particular, the first resist layer 38 is, for example, a positive photoresist that improves solubility in a specific developing solution by irradiation with ultraviolet light. The first resist layer 38 is dissolved in an alkaline solvent by, for example, irradiation with ultraviolet light. The first resist layer 38 is deposited, for example, by applying a solution containing a photosensitive resin material on the red main luminescent material layer 36R.

The first resist layer 38 may be soluble in a specific solvent regardless of presence or absence of exposure. For example, the first resist layer 38 may be soluble in propylene glycol monomethyl ether acetate (PGMEA), dimethyl sulfoxide (DMSO), or N-methylpyrrolidone (NMP). In addition, the first resist layer 38 may be a negative photoresist that acquires insolubility in a specific developing solution by irradiation with ultraviolet light.

Subsequently, the first resist layer 38 is exposed (step S12). Step S12 is a first exposure step of exposing the first resist layer 38. In step S12, for example, the first exposure step is performed as a preliminary step to remove a portion of the first resist layer 38. The first exposure step is performed, for example, by irradiating only the portion of the first resist layer 38 with ultraviolet light using a photomask.

Subsequently, the first resist layer 38 is developed (step S14). Step S14 is a first development step of developing the first resist layer 38. In step S14, the portion of the first resist layer 38 is removed, for example, by washing the first resist layer 38 with a specific developing solution.

In the present embodiment, only the first resist layer 38 formed at a position overlapping the green subpixel SPG is removed in step S14. Thus, at the time of completion of step S14, the red main luminescent material layer 36R is exposed at the position overlapping the green subpixel SPG.

Subsequently, a first etching step of etching a portion of the red main luminescent material layer 36R from a surface on a side of the first resist layer 38 is performed (step S16). The first etching step is performed, for example, by washing the red main luminescent material layer 36R exposed from the first resist layer 38 with a first etching solution in which the red main luminescent material layer 36R is soluble.

In the first etching step, only the red main luminescent material layer 36R exposed from the first resist layer 38 is etched at the position overlapping the green subpixel SPG. Thus, in step S16, the red main luminescent material layer 36R formed at the position overlapping the green subpixel SPG is removed.

The first etching solution contains, for example, the red first outer edge ligands 28R and water as a solvent. When the red main ligands 20R are soluble in non-polar solvents and the red first outer edge ligands 28R are soluble in polar solvents, the red main ligands 20R in the red light-emitting layer 10R at the position overlapping the green subpixel SPG are substituted with the red first outer edge ligands 28R by being in contact with the first etching solution. The red light-emitting layer 10R in which the ligands are substituted with the red first outer edge ligands 28R becomes soluble in water and removed by the first etching solution.

### Outer Edge Region Formation Step

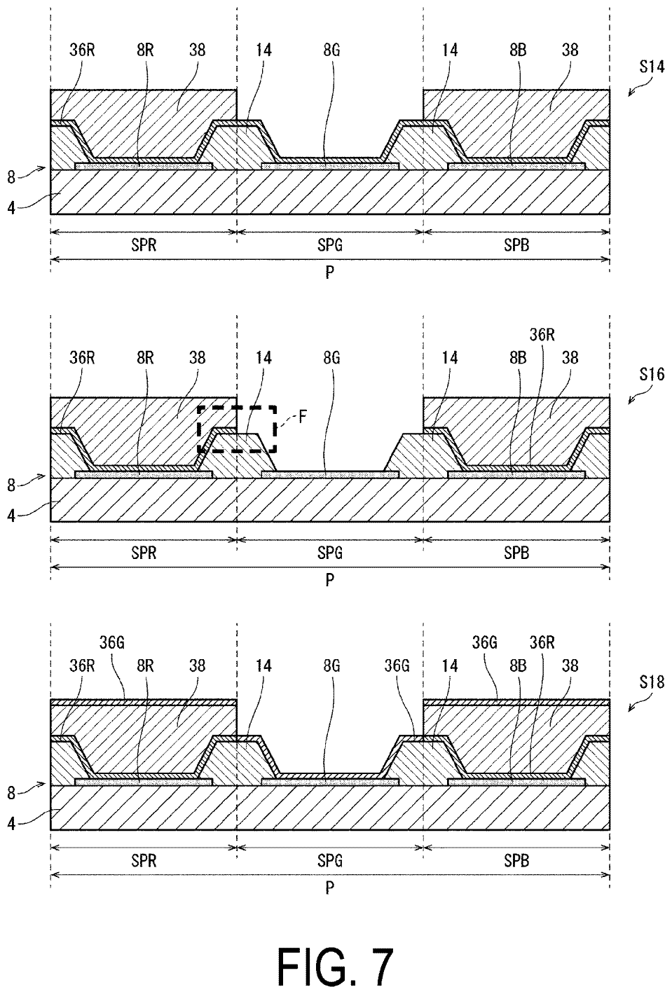

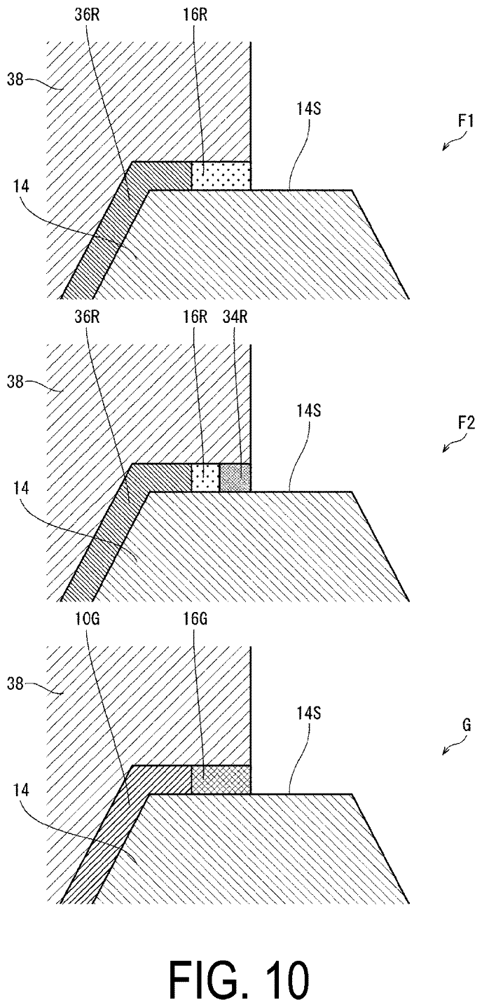

FIG. 10 is enlarged cross-sectional views of the display device 2 in the manufacturing process of the display device 2 according to the present embodiment. A region F1 illustrated in FIG. 10 is an example of an enlarged view of a region F illustrated in step S16 in FIG. 7. In step S16, an end face of the red main luminescent material layer 36R exposed from the first resist layer 38 comes into contact with the first etching solution, so that an edge of the red main luminescent material layer 36R, including the end face, is altered. A material at the altered position is different from the material contained in the red main luminescent material layer 36R.

The altered red main luminescent material layer 36R is not removed at least partially in step S16 because the altered red main luminescent material layer 36R overlaps the first resist layer 38. Thus, in step S16, the edge of the red main luminescent material layer 36R is altered and remains on the upper face 14S of the bank 14, thereby forming the red first outer edge region 16R. In other words, the first etching step is performed simultaneously with a first outer edge region formation step of forming the first outer edge region adjacent to at least one side surface of the first main luminescent material layer and having the first outer edge material different from the first main luminescent material. When forming the red first outer edge region 16R, the edge of the red main luminescent material layer 36R exposed from the first resist layer 38 may be partially removed by the first etching solution.

A region F2 illustrated in FIG. 10 is another example of an enlarged view of the region F illustrated in step S16 in FIG. 7. As illustrated in the region F2, in step S16, after etching the edge of the first main luminescent layer with the first etching solution, the edge of the first main luminescent layer may be further exposed to a different etching solution. Thus, by appropriately designing the etching conditions in step S16, in the first outer edge region formation step, the red second outer edge region 34R can be formed by further strongly altering the edge of the red main luminescent material layer 36R.

Although an example has been described in which water and the red first outer edge ligands 28R, which are dissolved in the water, are added to the first etching solution, the solvent and the ligands are not limited thereto. For example, the first etching solution may contain at least one polar solvent selected from the group consisting of methanol (MeOH), N,N-dimethylformamide (DMF), acetonitrile, ethylene glycol, and dimethyl sulfoxide (DMSO).

Alternatively, the first etching solution may contain the red first outer edge ligands 28R that are dissolved in the polar solvents described above. For example, the first etching solution may contain halogens containing S, Cl, Br, or I as the red first outer edge ligands 28R. Alternatively, the first etching solution may contain inorganic ligands containing S2- or may contain ligands for polar dispersion. Furthermore, the first etching solution may contain TMAH, TBAB, or 2-dimethylaminoethanethiol hydrochloride, as described above, as the red first outer edge ligands 28R.

When the first etching solution containing the red first outer edge ligands 28R comes into contact with the edge of the red main luminescent material layer 36R, the ligands coordinated to the red quantum dots 18R become in equilibrium between the red main ligands 20R and the red first outer edge ligands 28R, at the edge. Here, it is assumed that a concentration of the red first outer edge ligands 28R contained in the first etching solution is higher than a concentration of the main ligands 20R contained in the red main luminescent material layer 36R. In this case, the probability that many of the ligands coordinated to the red quantum dots 18R at the edge of the red main luminescent material layer 36R are replaced by the red first outer edge ligands 28R is increased. To be specific, the first etching solution may contain the red first outer edge ligands 28R of 0.013 mol/L or more.

Thus, in step S16, the red main ligands 20R coordinated to the red quantum dots 18R are replaced with the red first outer edge ligands 28R. In this case, the red quantum dots 18R coordinated with the red first outer edge ligands 28R become soluble in the water contained in the first etching solution, so only the red main luminescent material layer 36R, containing the red quantum dots 18R with the ligands substituted, is removed by the first etching solution. Therefore, at the time of completion of step S16, the red main luminescent material layer 36R remains only in the red subpixel SPR and the blue subpixel SPB.

In this case, the alteration of the edge of the red main luminescent material layer 36R corresponds to the substitution of the ligands coordinated to the red quantum dots 18R at the edge of the red main luminescent material layer 36R. Thus, at the edge of the red main luminescent material layer 36R, the red first outer edge region 16R is formed in which the main ligands 20R coordinated to the red quantum dots 18R are substituted with the red first outer edge ligands 28R. Therefore, in the case described above, the red first quantum dots 26R contained in the red first outer edge region 16R may have the same configuration as the red quantum dots 18R, except that the coordinating ligands are different.

### Relationship Between Development of Resist Layer and Etching of Main Luminescent Material Layer

The first development step and the first etching step may be performed simultaneously or sequentially in this order with the first etching solution. For example, when the first resist layer 38 is dissolved in PGMEA and is dissolved in alkali with ultraviolet irradiation, the first etching solution may be, for example, an alkaline solution containing a resist dissolving component, the red first outer edge ligands 28R, and water as a solvent. Thus, the first etching solution can also be used as a developing solution for the first resist layer 38. The red first outer edge ligands 28R are, for example, TMAH, and the resist dissolving component of the first etching solution is, for example, a TMAH developing solution (2.38 wt. %).

In this case, the first resist layer 38, which has become soluble in alkali due to the ultraviolet irradiation, is developed with the first etching solution. Further, the red main ligands 20R contained in the red light-emitting layer 10R exposed from the first resist layer 38 are substituted with the red first outer edge ligands 28R. The red light-emitting layer 10R becomes water-soluble by substituting the red main ligands 20R with the red first outer edge ligands 28R. Thus, the red light-emitting layer 10R in which some of the ligands are substituted with the red first outer edge ligands 28R is removed by the first etching solution.

Further, the first etching solution contains the red first outer edge ligands 28R. Thus, when the end face of the red light-emitting layer 10R comes into contact with the first etching solution, the red main ligands 20R coordinated to the red quantum dots 18R are substituted with the red first outer edge ligands 28R, which are different from the red main ligands 20R, at the outer edge of the red light-emitting layer 10R. Thus, the red first outer edge region 16R is formed at the outer edge of the red light-emitting layer 10R. That is, the development of the first resist layer 38, the etching of the red light-emitting layer 10R, and the formation of the red first outer edge region 16R may be performed simultaneously or sequentially in this order with the first etching solution.

The first etching solution may separately contain a solute that makes an aqueous solution containing this solute alkaline. For example, an aqueous solution containing KOH may be used as the alkaline first etching solution. The first etching solution may contain the red first outer edge ligands 28R that exhibit alkalinity when dispersed in a solvent. For example, when the first etching solution contains the TMAH described above as the red first outer edge ligands 28R, the first etching solution exhibits alkalinity. Thus, when the first etching solution contains the red first outer edge ligands 28R that exhibit alkalinity when dispersed in the solvent, a separate solute for making the first etching solution alkaline is not necessary to be added to the first etching solution, thereby reducing material costs.

The first etching solution may contain a non-polar organic solvent and the red first outer edge ligands 28R that are dissolved in this non-polar organic solvent. As the red first outer edge ligands 28R, which are dissolved in non-polar organic solvents, for example, hydrophobic ligands described above can be employed. The non-polar organic solvent may contain, for example, at least one selected from the group consisting of hexane, heptane, octane, nonane, decane, undecane, toluene, and dodecane.

In this case, in step S14, the red quantum dots 18R coordinated with the red first outer edge ligands 28R become soluble in the non-polar organic solvent contained in the first etching solution. Thus, only the red main luminescent material layer 36R containing the red quantum dots 18R with the ligands substituted is removed by the first etching solution containing the non-polar organic solvent.

In addition, in step S14, at the edge of the red main luminescent material layer 36R, the ligands coordinated to the red quantum dots 18R contained in the red main luminescent material layer 36R are substituted with the hydrophobic red first outer edge ligands 28R. Therefore, in the case described above, in step S14, the hydrophobic red first outer edge region 16R can be formed at the edge of the red main luminescent material layer 36R.

Alternatively, the first etching solution may contain an acid aqueous solution. In this case, the etching in step S14 may be performed by oxidation of the red main luminescent material layer 36R with the acid aqueous solution. The acid aqueous solution may contain, for example, at least one acid selected from the group consisting of hydrochloric acid, sulfuric acid, hydrogen peroxide, hydrofluoric acid, formic acid, and acetic acid.

The first resist layer 38 may be soluble in the acid aqueous solution after exposure. In this case, in step S12, by adopting the acid aqueous solution as the developing solution and continuing the washing after the removal of the first resist layer 38, removal of the red main luminescent material layer 36R can be performed following the development of the first resist layer 38.

In this case, in step S14, at the edge of the red main luminescent material layer 36R, the red quantum dots 18R contained in the red main luminescent material layer 36R are oxidized with the acid aqueous solution contained in the etching solution. Therefore, in the case described above, in step S14, the red first outer edge region 16R containing the red first quantum dots 26R obtained by oxidizing the red quantum dots 18R can be formed at the edge of the red main luminescent material layer 36R. Here, the thickness T32R of the shells 32R of the red first quantum dots 26R may become thinner than the thickness T24R of the shells 24R of the red quantum dots 18R due to the acid aqueous solution.

### Patterning of Green Main Luminescent Material Layer by Peeling Off First Resist Layer

After the step of etching the red main luminescent material layer 36R, a green main luminescent material layer 36G containing the main luminescent material contained in the green light-emitting layer 10G as a second main luminescent material is deposited as a second main luminescent material layer (step S18). Step S18 is a second main luminescent material deposition step of depositing the second main luminescent material layer containing the second main luminescent material. Here, the green main luminescent material layer 36G is formed on the first resist layer 38 at a position overlapping the remaining first resist layer 38. The deposition of the green main luminescent material layer 36G may be performed by the same method as the deposition of the red main luminescent material layer 36R, except that the material contained in the layer to be deposited is different.

Subsequently, the remaining first resist layer 38 is peeled off (step S20). Step S20 is a first peeling step. For example, when the first resist layer 38 is soluble in an organic solvent containing PEGMA, the first resist layer 38 may be peeled off by washing the first resist layer 38 with this organic solvent. Thus, the green main luminescent material layer 36G formed on the first resist layer 38 is also removed simultaneously with the peeling-off of the first resist layer 38. Therefore, in step S20, the green main luminescent material layer 36G remains only at the position overlapping the green subpixel SPG.

### Second Etching Step

Subsequently, a second resist layer 40 is deposited on the red main luminescent material layer 36R and the green main luminescent material layer 36G (step S22). The second resist layer 40 according to the present embodiment may have the same configuration as the first resist layer 38. The deposition of the second resist layer 40 may be performed using the same method as in step S10.

Subsequently, the second resist layer 40 is exposed (step S24). Step S24 is a second exposure step of exposing the second resist layer. In step S24, for example, the second exposure step is performed as a preliminary step to remove a portion of the second resist layer 40. The second exposure step may be performed by exposing the second resist layer 40 using the same method as performed in the first exposure step.

Subsequently, the second resist layer 40 is developed (step S26). Step S26 is a second development step of developing the second resist layer 40. In step S26, the portion of the second resist layer 40 is removed, for example, by washing the second resist layer 40 with a specific developing solution.

In the present embodiment, only the second resist layer 40 formed at a position overlapping the blue subpixel SPB is removed in step S26. Thus, at the time of completion of step S26, the red main luminescent material layer 36R is exposed at the position overlapping the blue subpixel SPB.

Subsequently, a second etching step of etching a portion of the red main luminescent material layer 36R from the surface on a side of the second resist layer 40 is performed (step S28). The second etching step is performed, for example, by washing the red main luminescent material layer 36R exposed from the second resist layer 40 with a second etching solution in which the red main luminescent material layer 36R is soluble. The second etching solution may have the same configuration as the first etching solution described above.

In the second etching step, only the red main luminescent material layer 36R exposed from the second resist layer 40 is etched at the position overlapping the blue subpixel SPB. Thus, in step S28, the red main luminescent material layer 36R formed at the position overlapping the blue subpixel SPB is removed.

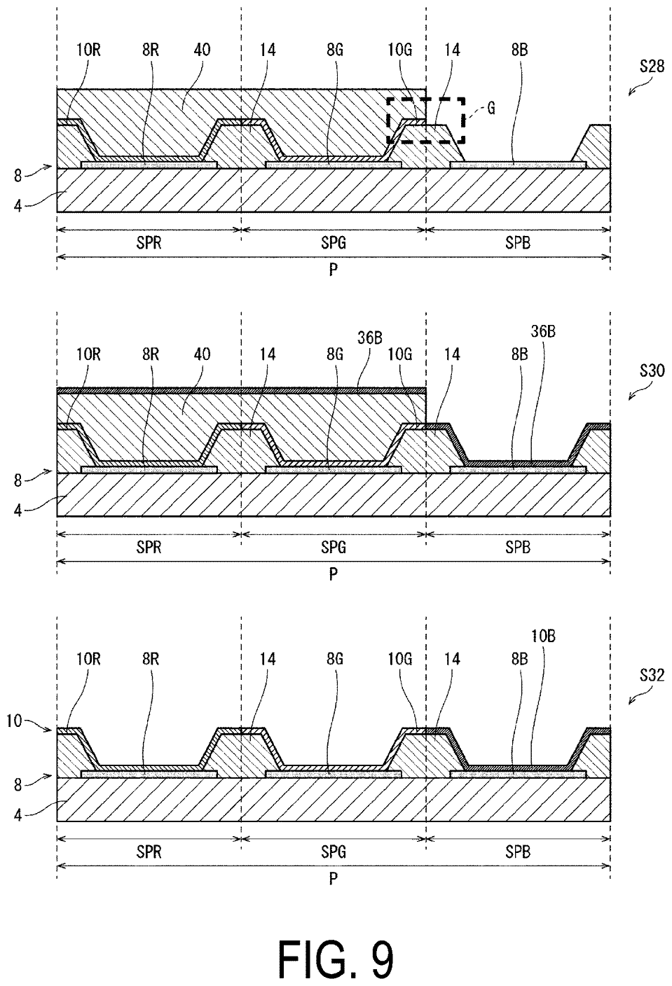

A region G illustrated in FIG. 10 is an example of an enlarged view of a region G illustrated in step S28 in FIG. 9. In step S28, also at a position overlapping the second resist layer 40, an edge of the green main luminescent material layer 36G exposed from the second resist layer 40 comes into contact with the second etching solution, so that the vicinity of the edge is altered. A material at the altered position is different from the material contained in the green main luminescent material layer 36G.

The altered green main luminescent material layer 36G is not removed in step S28 because the altered green main luminescent material layer 36G overlaps the second resist layer 40. Thus, in step S28, the edge of the green main luminescent material layer 36G is altered and remains on the upper face 14S of the bank 14, thereby forming the green first outer edge region 16G. In other words, the second etching step is performed simultaneously with a second outer edge region formation step of forming the second outer edge region adjacent to at least one side surface of the second main luminescent material layer and having the second outer edge material different from the second main luminescent material.

Thus, at the time of completion of step S28, formation of the green light-emitting layer 10G including the green main region 15G and the green first outer edge region 16G at the position overlapping the green subpixel SPG is completed. In addition, at the time of completion of step S28, the red main luminescent material layer 36R at the position overlapping the blue subpixel SPB is removed.

The green first outer edge region 16G may be formed using the same method as the method of forming the red first outer edge region 16R, described above. In other words, the development of the second resist layer 40, the etching of the red main luminescent material layer 36R, and the formation of the green first outer edge region 16G in step S26 and step S28 may be performed simultaneously. When forming the green first outer edge region 16G, the edge of the green main luminescent material layer 36G exposed from the second resist layer 40 may be partially removed by the second etching solution.

### Patterning of Blue Main Luminescent Material Layer by Peeling Off Second Resist Layer

Subsequently, a blue main luminescent material layer 36B containing the main luminescent material contained in the blue light-emitting layer 10B as a third main luminescent material is deposited as a third main luminescent material layer (step S30). Here, the blue main luminescent material layer 36B is formed on the second resist layer 40 at the position overlapping the remaining second resist layer 40. The deposition of the blue main luminescent material layer 36B may be performed using the same method as the deposition of the red main luminescent material layer 36R or the green main luminescent material layer 36G, except that the material contained in the layer to be deposited is different.

Subsequently, the remaining second resist layer 40 is peeled off (step S32). The peeling-off of the second resist layer 40 may be performed using the same method as the peeling-off of the first resist layer 38 in step S20 described above. Thus, the blue main luminescent material layer 36B formed on the second resist layer 40 is also removed simultaneously with the peeling-off of the second resist layer 40. Therefore, in step S32, the blue main luminescent material layer 36B remains only at the position overlapping the blue subpixel SPB.

Therefore, at the time of completion of step S32, formation of the blue light-emitting region LAB including the blue light-emitting layer 10B at the position overlapping the blue subpixel SPB is completed, and the formation of the light-emitting layer 10 are completed. In the blue light-emitting region LAB formation step, there is no step of etching a layer adjacent to the blue light-emitting layer 10B. Thus, no outer edge region is formed in the blue light-emitting region LAB.

Subsequently, the common electrode 12 common to the plurality of subpixels is formed on the light-emitting layer 10 (step S34), thereby completing the formation of the light-emitting element layer 6. The common electrode 12 may be deposited using the same method as the method of depositing the conductive material in the step of forming the pixel electrode 8. In the method for manufacturing the display device 2 according to the present embodiment, a sealing layer may be formed on the light-emitting element layer 6 after the step of forming the light-emitting element layer 6. Through the above steps, the display device 2 according to the present embodiment is manufactured.

### Example of Subpixel Formation Pattern

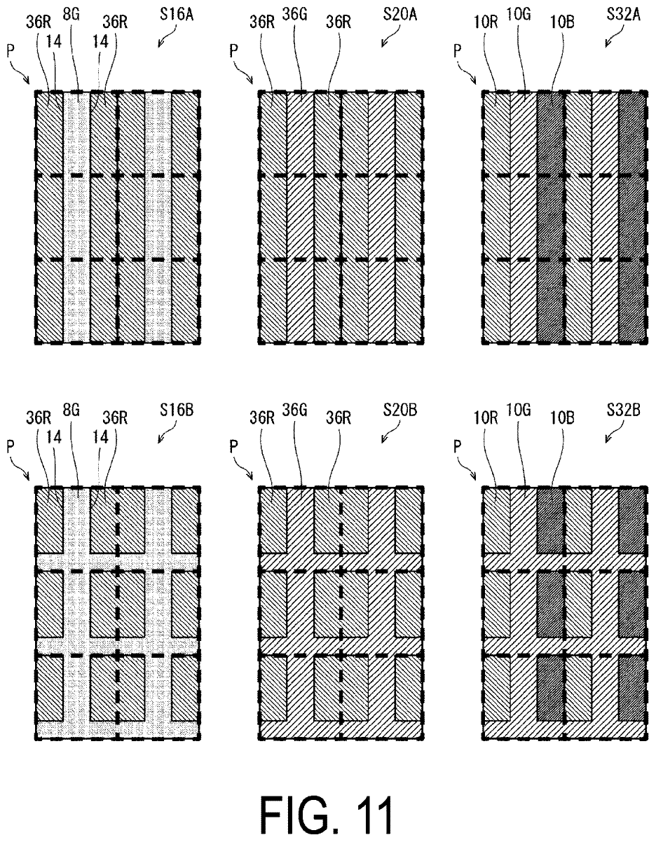

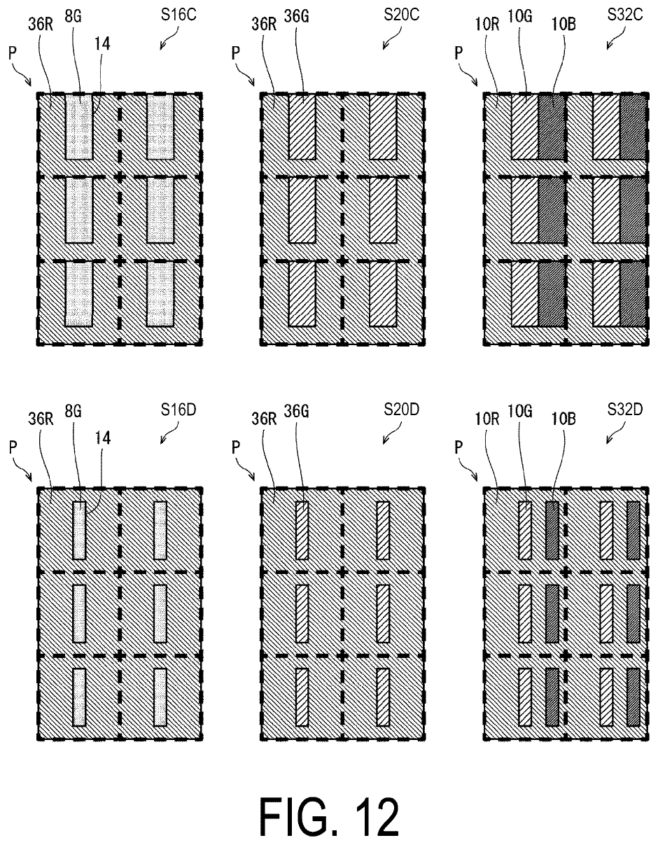

Formation patterns of the subpixels included in the display device 2 according to the present embodiment will be described with reference to FIG. 11 and FIG. 12. FIG. 11 and FIG. 12 are plan views illustrating steps of the display device 2 in some steps of the method for manufacturing the display device 2 according to the present embodiment.

In each of the plan views illustrating steps in this specification, a total of six pixels P, two pixels in a horizontal direction and three pixels in a vertical direction toward the paper surface are extracted and illustrated in a plan view. In the plan views illustrating steps in this specification, boundaries between the pixels P are indicated by dotted lines. Further, in the plan views illustrating steps in this specification, the outer edge regions are omitted for simplicity of illustration. In addition, in the plan views illustrating steps in this specification, for simplicity of illustration, the resist layer is omitted, and the resist layer is illustrated transparently.

In the present embodiment, each of the red light-emitting region LAR, the green light-emitting region LAG, and the blue light-emitting region LAB may be continuously formed over a plurality of pixels. In particular, each of the red light-emitting region LAR, the green light-emitting region LAG, and the blue light-emitting region LAB may be formed in a belt shape over a plurality of pixels. In this case, step S16, step S20, and step S32 in the manufacturing method according to the present embodiment are performed so as to obtain, for example, structures illustrated in step S16A, step S20A, and step S32A in FIG. 11, respectively.

In the present embodiment, any one of the red light-emitting region LAR, the green light-emitting region LAG, and the blue light-emitting region LAB may be continuously formed over all the pixels. In this case, step S16, step S20, and step S32 in the manufacturing method according to the present embodiment are performed so as to obtain, for example, structures illustrated in step S16B, step S20B, and step S32B in FIG. 11, respectively. Thus, as illustrated in step S32B in FIG. 11, the display device 2 in which the green light-emitting region LAG is formed in common to all the pixels can be manufactured.

Alternatively, step S16, step S20, and step S32 in the manufacturing method according to the present embodiment may be performed so as to obtain, for example, structures illustrated in step S16C, step S20C, and step S32C in FIG. 12, respectively. Thus, as illustrated in step S32C in FIG. 12, the display device 2 in which the red light-emitting region LAR is formed in common to all the pixels can be manufactured.

When the display device 2 has the structure illustrated in step S32C in FIG. 12, not only the edge of the green main luminescent material layer 36G but also an edge of the red main luminescent material layer 36R is exposed from the second resist layer 40 in step S28. Thus, when the display device 2 has the structure illustrated in step S32C in FIG. 12, the red first outer edge region 16R is formed at the edge of the red main luminescent material layer 36R also in step S28.

Furthermore, in the present embodiment, one type of light-emitting region may be provided in common to all the pixels, and the remaining two types of light-emitting regions may be provided in island shapes. In this case, step S16, step S20, and step S32 in the manufacturing method according to the present embodiment are performed so as to obtain, for example, structures illustrated in step S16D, step S20D, and step S32D in FIG. 12, respectively. Thus, as illustrated in step S32D in FIG. 12, the display device 2 can be manufactured in which island-shaped green light-emitting regions LAG and blue light-emitting regions LAB are formed to be surrounded by a common red light-emitting region LAR.

When the display device 2 has the structure illustrated in step S32D in FIG. 12, only the edge of the red main luminescent material layer 36R is exposed from the second resist layer 40 in step S28. Thus, when the display device 2 has the structure illustrated in step S32D in FIG. 12, the red first outer edge region 16R is formed only at the edge of the red main luminescent material layer 36R in step S28. Therefore, in the display device 2 having the structure illustrated in step S32D in FIG. 12, only the green light-emitting layer 10G is formed in the green light-emitting region LAG, and the green first outer edge region 16G is not formed.

### Effects Related to Manufacturing Method

In a light-emitting layer formation process in a method for manufacturing a display device using a known lift-off method, for example, a resist layer is first deposited on an entire surface of a substrate, and then the resist layer is exposed and developed in order to remove the resist layer in a region where the light-emitting layer is to be formed. Subsequently, the light-emitting layer is formed by depositing a main luminescent material layer on the entire surface of the substrate, peeling off the remaining resist layer with a solvent, and lifting off the main luminescent material layer in regions other than the region where the light-emitting layer is to be formed. In the above manufacturing method, for example, in a manufacturing process of a display device including subpixels of three colors, the steps described above are performed for each color, and thus the steps are performed three times.

In the present embodiment, even in the method for manufacturing the display device including the subpixels of three colors, the number of times the resist layer is deposited can be reduced to two (S10 and S22) compared to the known lift-off method. In the present embodiment, the exposure (S12 and S24) and the development (S14 and S26) of the resist layer are also performed twice each, which can reduce the number of steps compared to the known lift-off method. In the present embodiment, when the lift-off step is performed twice and the first development step and the first etching step are simultaneously or sequentially performed with the first etching solution, the number of steps can be reduced. Furthermore, in the present embodiment, since there is no step of lifting off a plurality of layers in which a plurality of layered layers are lifted off at once, lift-off can be easily performed.

In the present embodiment, since the number of times of photolithography of the resist layer is reduced, alignment of each light-emitting region can be performed more strictly in the above manufacturing method. Misalignment of the first outer edge region of each light-emitting region does not greatly affect display by the display device 2 as compared to misalignment of the main region. Thus, in the above manufacturing method, a tolerance of the misalignment of each light-emitting region is widened. Therefore, the above manufacturing method is advantageous in that the high-definition display device 2 can be manufactured more easily.

In the method for manufacturing the display device 2 according to the present embodiment, only the red main luminescent material layer 36R is formed as a layer containing a material different from the material contained in the light-emitting region to be originally formed at positions overlapping the green subpixel SPG and the blue subpixel SPB, respectively. In other words, in this manufacturing method, the green main luminescent material layer 36G is not formed at the position overlapping the blue subpixel SPB. Thus, according to this manufacturing method, the type of main luminescent material formed at positions different from a position where this main luminescent material should be formed can be limited to one type, reducing probability that color mixing occurs.

In addition, in the method for manufacturing the display device 2 according to the present embodiment, the development in the step of patterning each resist layer, the etching of the red main luminescent material layer 36R, and the formation of each first outer edge region can be performed in the same step. These steps can be performed by appropriately designing the developing solutions in the steps of patterning the respective resist layers and the etching solution for etching the red main luminescent material layer 36R. With the above steps, the method for manufacturing the display device 2 according to the present embodiment can reduce the number of required steps and material costs.

A charge transport layer or a charge injection layer common to adjacent subpixels may be formed in the light-emitting element. In this case, there is a region in which a current path between the pixel electrode and the common electrode is partitioned only by the charge transport layer or the charge injection layer, which may result in a large unwanted leakage current. In the present embodiment, in the subpixels adjacent to each other, the light-emitting layers are formed in contact with each other. Accordingly, even when the charge transport layer or the charge injection layer is formed in common for the adjacent subpixels, the number of layers formed in the current path between the pixel electrode and the common electrode is increased, so that unwanted leakage current can be suppressed and power consumption can be reduced.

Further, the etching of the red main luminescent material layer 36R and the patterning of the green main luminescent material layer 36G are performed using the first resist layer 38 having the same pattern. Therefore, according to the above manufacturing method, the red light-emitting region LAR and the green light-emitting region LAG are brought into close contact with each other, and space between the red light-emitting region LAR and the green light-emitting region LAG can be reduced. For the same reason, according to the above manufacturing method, the green light-emitting region LAG and the blue light-emitting region LAB are brought into close contact with each other, and space between the green light-emitting region LAG and the blue light-emitting region LAB can be reduced.

In the method for manufacturing the display device 2 according to the present embodiment, the first resist layer 38 and the second resist layer 40 are peeled off in separate steps. Thus, with the above configuration, the first resist layer 38 and the second resist layer 40 can be peeled off more easily than when the first resist layer 38 and the second resist layer 40 are simultaneously peeled off in the same step. With the above configuration, conditions of the solutions used for peeling off the first resist layer 38 and the second resist layer 40 are eased, so the solutions having less influence on members other than the resist layers can be used.

In the present embodiment, the etching of the red main luminescent material layer and the formation of the outer edge region in the red main luminescent material layer are performed together. Thus, in a configuration in which the outer edge region can prevent penetration of moisture or the like, the main region is protected by the outer edge region from moisture due to washing or the like with water during the manufacturing process, so that the function of the main region is prevented from deterioration due to permeation or the like of moisture into the main region.

### Second Embodiment

### Etching of Two Types of Main Luminescent Material Layers

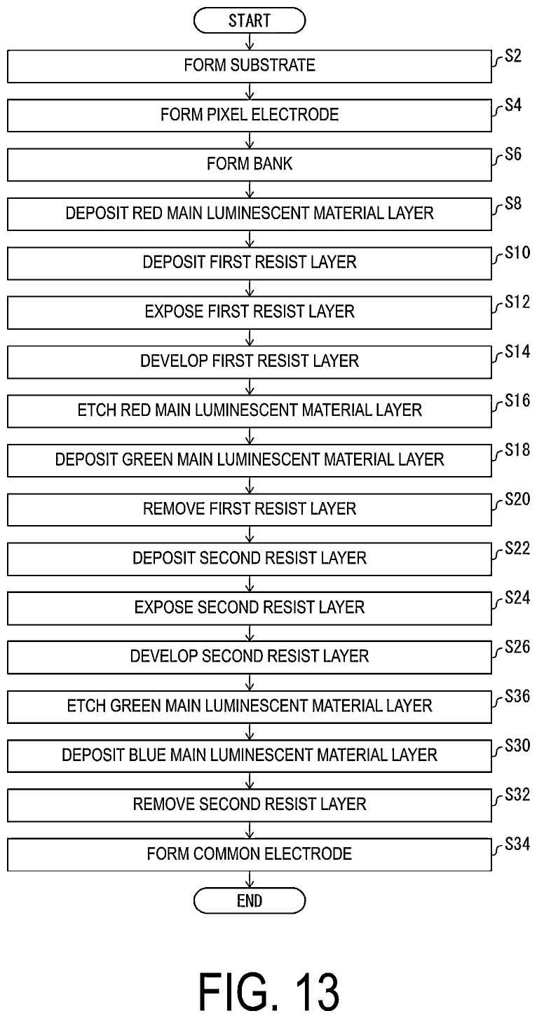

A display device 2 according to the present embodiment has the same configuration as the display device 2 according to the previous embodiment except for a difference in the manufacturing method. A method for manufacturing the display device 2 according to the present embodiment will be described with reference to FIG. 13 to FIG. 17. Note that, in the present specification, each member having the same function is denoted by the same name and the same reference numeral, and the same description will not be repeated as long as there is no difference in configurations.

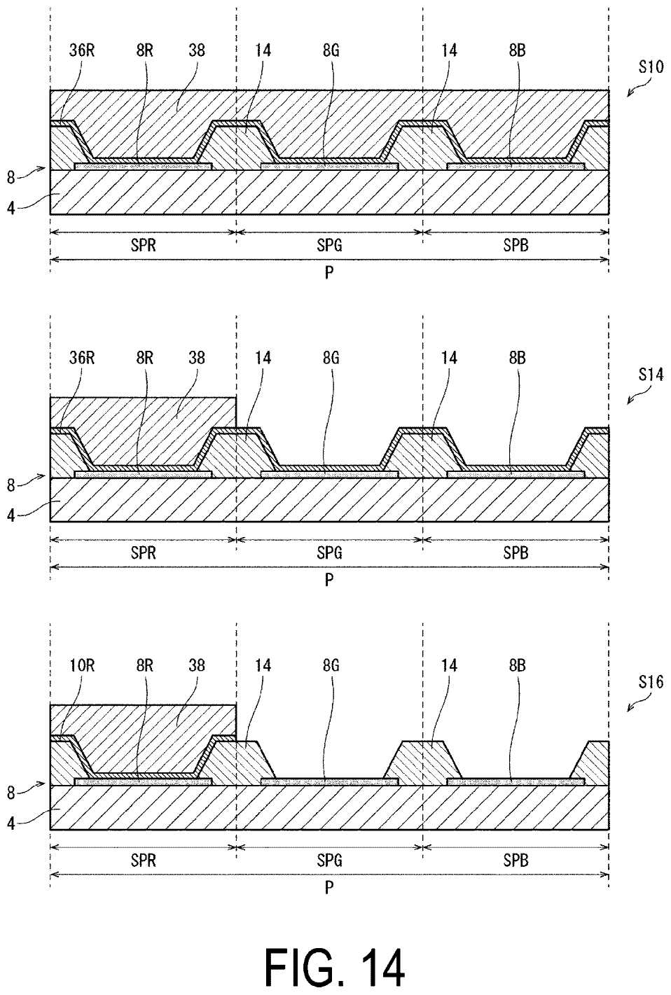

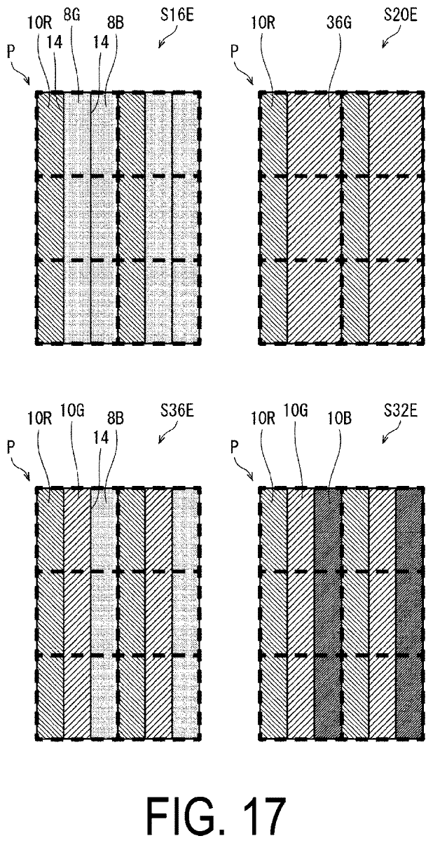

FIG. 13 is a flowchart for describing the method for manufacturing the display device 2 according to the present embodiment. FIG. 14 to FIG. 16 are cross-sectional views illustrating steps of the display device 2 in some steps of the method for manufacturing the display device 2 according to the present embodiment. FIG. 17 is plan views illustrating steps of the display device 2 in some steps of the method for manufacturing the display device 2 according to the present embodiment.

The method for manufacturing the display device 2 according to the present embodiment is performed using the same method as the method for manufacturing the display device 2 according to the previous embodiment up to step S10 described above. Thus, in the present embodiment, at the time of completion of step S10, a structure illustrated in S10 in FIG. 14 is obtained.

Following step 10, a first exposure step is performed using the same method as in step S12 according to the previous embodiment. Here, in step S12 in the present embodiment, exposure is performed as a preliminary step to remove a first resist layer 38 formed at a position overlapping a blue subpixel SPB in addition to the first resist layer 38 formed at a position overlapping a green subpixel SPG.

Following step S12, a first development step is performed using the same method as in step S14 according to the previous embodiment. Here, in step S14 in the present embodiment, the first resist layer 38 formed at the position overlapping the blue subpixel SPB is also removed together with the first resist layer 38 formed at the position overlapping the green subpixel SPG. Thus, at the time of completion of step S14, a red main luminescent material layer 36R is exposed at the positions overlapping the green subpixel SPG and the blue subpixel SPB, respectively.

Subsequently, a first etching step is performed using the same method as in step S16 according to the previous embodiment. Also in the present embodiment, only the red main luminescent material layer 36R exposed from the first resist layer 38 is etched. Therefore, in step S16, as illustrated in step S16 in FIG. 14 and step S16E in FIG. 17, the red main luminescent material layer 36R formed at the positions overlapping the green subpixel SPG and the blue subpixel SPB, respectively is removed.

Also in the present embodiment, by appropriately designing a first etching solution, the first exposure step, the first development step, and the formation of a red first outer edge region 16R in the red main luminescent material layer 36R may be performed simultaneously. However, in the present embodiment, the red main luminescent material layer 36R is removed from the position overlapping the blue subpixel SPB in addition to the position overlapping the green subpixel SPG. Therefore, at the time point when the formation of the red first outer edge region 16R in the red main luminescent material layer 36R that is formed at a position overlapping a remaining red subpixel SPR is completed, formation of a red light-emitting layer 10R is completed, and thus formation of a light-emitting region LAR is completed.

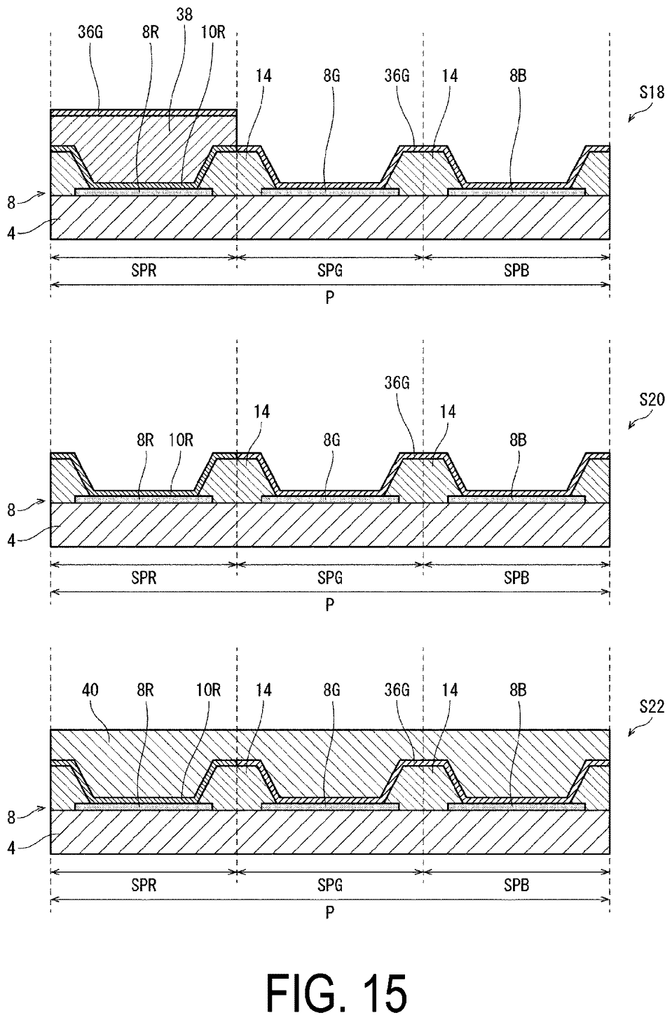

Subsequently, a green main luminescent material layer 36G is formed using the same method as in step S18 according to the previous embodiment. Here, in the present embodiment, the first resist layer 38 remains only at the position overlapping the red subpixel SPR. Subsequently, the first resist layer 38 is peeled off using the same method as in step S20 according to the previous embodiment. Thus, as illustrated in step S20 in FIG. 15 and step S20E in FIG. 17, the green main luminescent material layer 36G remains at the positions overlapping the green subpixel SPG and the blue subpixel SPB, respectively.

Subsequently, a second resist layer 40 is deposited using the same method as in step S22 according to the previous embodiment. Subsequently, a second exposure step is performed using the same method as in step S24 according to the previous embodiment, and then a second development step is performed using the same method as in step S26 according to the previous embodiment. In the present embodiment, when step S26 is completed, the green main luminescent material layer 36G is exposed from the second resist layer 40 at the position overlapping the blue subpixel SPB.

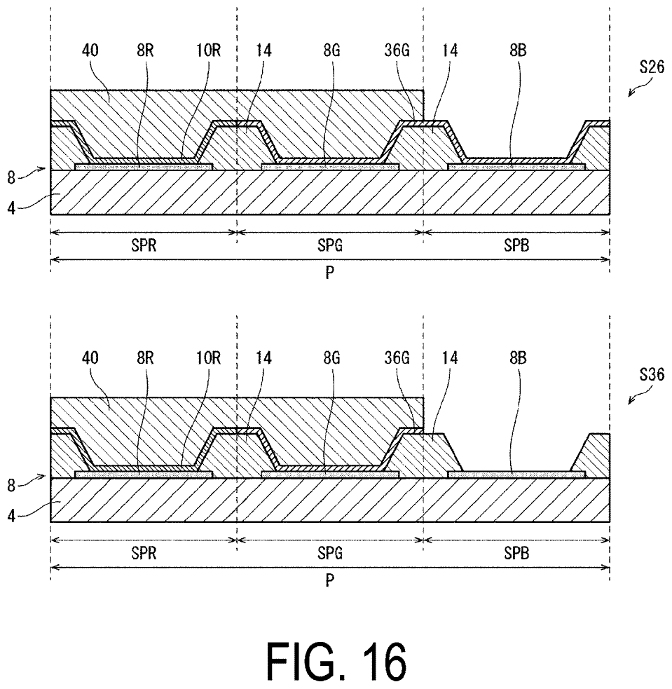

Subsequently, a second etching step of etching a portion of the green main luminescent material layer 36G from a surface on a side of the second resist layer 40 is performed (step S36). In the second etching step in the present embodiment, in particular, only the green main luminescent material layer 36G exposed from the second resist layer 40 is etched at the position overlapping the blue subpixel SPB. Thus, in step S36, as illustrated in step S36 in FIG. 16 and step S36E in FIG. 17, the green main luminescent material layer 36G formed at the position overlapping the blue subpixel SPB is removed.

A second etching solution used in the second etching step according to the present embodiment may be the same as the second etching solution according to the previous embodiment. Further, the second etching step according to the present embodiment may be performed using the same method as the second etching step according to the previous embodiment, except that a type of the main luminescent material layer to be removed by etching is different. In other words, in the present embodiment, a second photolithography step, the second etching step, and formation of a green first outer edge region 16G in the green main luminescent material layer 36G may be performed simultaneously.

As illustrated in FIG. 16, at the time of completion of step S36, the same structure as the structure obtained at the time of completion of step S28 according to the previous embodiment is obtained. Thereafter, the display device 2 according to the present embodiment is obtained by sequentially performing the same steps from step S30 to step S34 according to the previous embodiment. In the present embodiment, as illustrated in step S32E in FIG. 17, each of the red light-emitting region LAR, the green light-emitting region LAG, and the blue light-emitting region LAB may be formed in a belt shape over a plurality of pixels.

Also in the present embodiment, the red light-emitting region LAR can be formed in the etching step using the resist layer used for patterning the other light-emitting regions. Thus, according to the method for manufacturing the display device 2 according to the present embodiment, the number of required steps can be reduced.

In the present embodiment, step S20 can be performed only by peeling off the first resist layer 38 from the position overlapping the red subpixel SPR. Therefore, the first resist layer 38 can be peeled off more easily in step S20.

### Third Embodiment

### Simultaneous Etching of Two Types of Main Luminescent Material Layers

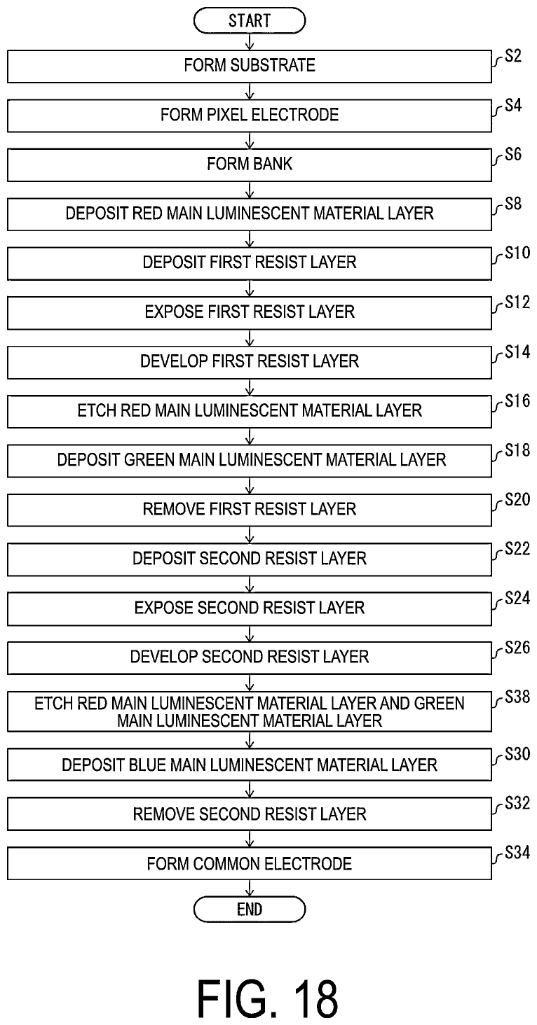

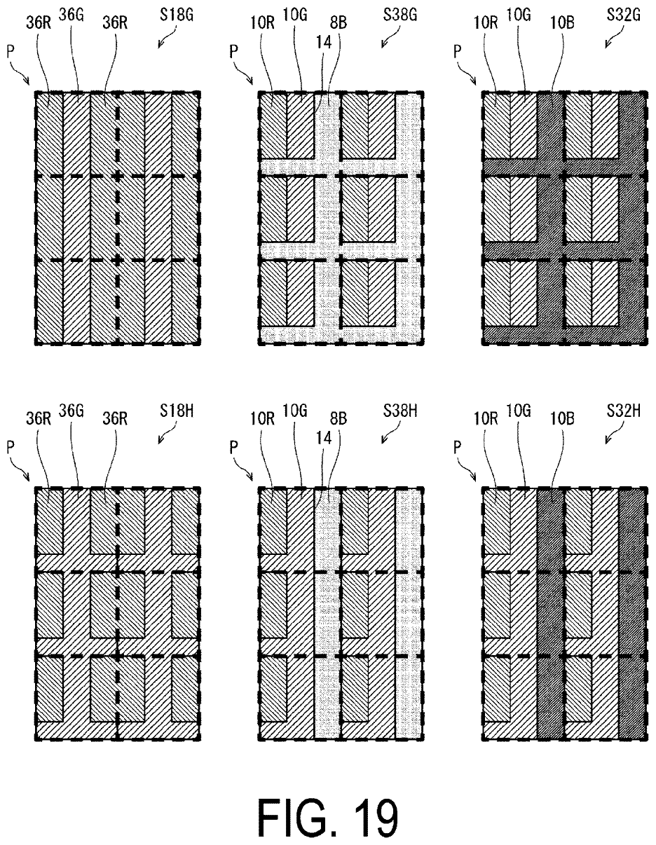

A display device 2 according to the present embodiment has the same configuration as the display device 2 according to each of the previous embodiments, except for a difference in a manufacturing method. The method for manufacturing the display device 2 according to the present embodiment will be described with reference to FIG. 18 and FIG. 19. FIG. 18 is a flowchart for describing the method for manufacturing the display device 2 according to the present embodiment. FIG. 19 is plan views illustrating steps of the display device 2 in some steps of the method for manufacturing the display device 2 according to the present embodiment.

The method for manufacturing the display device 2 according to the present embodiment is performed using the same method as the method for manufacturing the display device 2 according to the first embodiment up to step S26 described above. For example, in the present embodiment, a structure illustrated in step S18G in FIG. 19 may be formed at the time of completion of step S18.

However, in the method for manufacturing the display device 2 according to the present embodiment, both a red main luminescent material layer 36R and a green main luminescent material layer 36G remain at positions overlapping the blue subpixel SPB at a time of completion of step S26. Thus, at the time of completion of step S26, both the red main luminescent material layer 36R and the green main luminescent material layer 36G are exposed from the second resist layer 40 at the positions overlapping the blue subpixel SPB.

Following step S26, a second etching step of etching portions of the red main luminescent material layer 36R and a portion of the green main luminescent material layer 36G from a surface on a side of the second resist layer 40 is performed (step S38). In the second etching step of the present embodiment, in particular, only the red main luminescent material layer 36R and the green main luminescent material layer 36G exposed from the second resist layer 40 are etched at the positions overlapping the blue subpixel SPB. Thus, in step S38, as illustrated in step S38G in FIG. 19, the red main luminescent material layer 36R and the green main luminescent material layer 36G formed at the positions overlapping the blue subpixel SPB are removed.

When the red main luminescent material layer 36R and the green main luminescent material layer 36G are removed in step S38, side surfaces of both the red main luminescent material layer 36R and the green main luminescent material layer 36G are exposed from the second resist layer 40. Thus, in step S38, formation of a red first outer edge region 16R in the red main luminescent material layer 36R and formation of a green first outer edge region 16G in the green main luminescent material layer 36G both are performed.

A second etching solution used in the second etching step according to the present embodiment may be the same as the second etching solution according to each of the embodiments described above. Further, the second etching step according to the present embodiment may be performed using the same method as the second etching step according to each of the embodiments described above, except that types of the main luminescent material layers to be removed by etching are different. In other words, in the present embodiment, a second photolithography step, the second etching step, and the formation of the first outer edge regions in the red main luminescent material layer 36R and the green main luminescent material layer 36G may be performed simultaneously.

The display device 2 according to the present embodiment is obtained by sequentially performing the same steps as steps S30 through S34 according to each of the embodiments described above, following step S38. In the present embodiment, as illustrated in step S32G in FIG. 19, a blue light-emitting region LAB may be continuously formed over all the pixels.

Alternatively, step S18, step S38, and step S32 in the manufacturing method according to the present embodiment may be performed so as to obtain, for example, structures illustrated in step S18H, step S38H, and step S32H in FIG. 19, respectively. Thus, as illustrated in step S32H in FIG. 19, the display device 2 can be manufactured in which only the red light-emitting region LAR is independently formed in each pixel, and the green light-emitting region LAG and the blue light-emitting region LAB are formed in common for a plurality of pixels, respectively.

Also in the present embodiment, the red light-emitting region LAR can be formed in the etching step using the resist layer used for patterning the other light-emitting regions. Thus, according to the method for manufacturing the display device 2 according to the present embodiment, the number of required steps can be reduced.

In the present embodiment, in step S38, both the red main luminescent material layer 36R and the green main luminescent material layer 36G are removed by etching at the positions overlapping the blue subpixel SPB. Thus, in step S38, the first outer edge regions can be formed simultaneously in a plurality of types of main luminescent material layers, respectively. Therefore, in the method for manufacturing the display device 2 according to the present embodiment, the first outer edge regions can be formed more efficiently.

### Fourth Embodiment

### Display Device Including Wavelength Conversion Layer

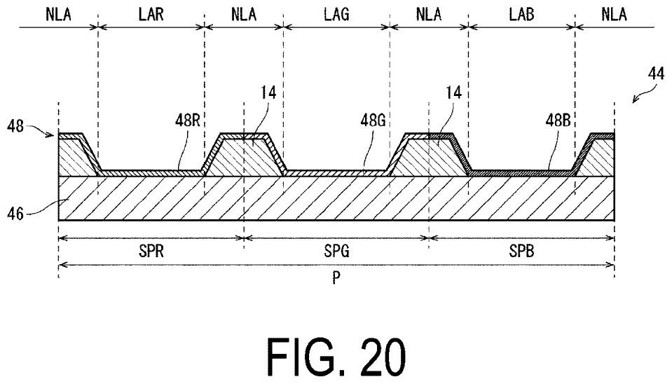

FIG. 20 is a schematic cross-sectional view of a display device 44 according to the present embodiment. In a plan view, the display device 44 according to the present embodiment includes a display region DA in which light emitted from each subpixel is extracted for display and a frame region NA that surrounds the display region DA, as the display device 2 illustrated in FIG. 2. FIG. 20 illustrates part of a cross section at a position overlapping the display region DA in a plan view, similar to the cross-sectional view of the display device 2 illustrated in FIG. 1.

As illustrated in FIG. 20, the display device 44 according to the present embodiment includes a light source unit 46, a bank 14 on the light source unit 46, and a wavelength conversion layer 48 as a light emitting member on the light source unit 46 and the bank 14. Note that, in this specification, when viewed from the bank 14, a direction to the light source unit 46 is described as “downward direction”, and a direction to the wavelength conversion layer 48 is described as “upward direction”.

The light source unit 46 irradiates the wavelength conversion layer 48 with light. The wavelength conversion layer 48 absorbs light from the light source unit 46 and emits light of a different wavelength from the light from the light source unit 46. In other words, the wavelength conversion layer 48 is a light-emitting layer that emits light by absorbing light, including light from the light source unit 46. The wavelength conversion layer 48 according to the present embodiment includes a plurality of light-emitting regions, including a red light-emitting region LAR, a green light-emitting region LAG, and a blue light-emitting region LAB. In particular, each light-emitting region of the wavelength conversion layer 48 emits light of a longer wavelength than light each light-emitting region absorbs.

In the present embodiment, the display device 44 includes a plurality of subpixels, and the wavelength conversion layer 48 includes the light-emitting regions, one for each of the subpixels. In the present embodiment, for example, the wavelength conversion layer 48 includes, as the light-emitting regions, the red light-emitting region LAR in a red subpixel SPR, the green light-emitting region LAG in a green subpixel SPG, and the blue light-emitting region LAB in a blue subpixel SPB.

In the present embodiment, the red light-emitting region LAR is a red PL emission region and includes a red wavelength conversion layer 48R that emits red light. The green light-emitting region LAG is a green PL emission region and includes a green wavelength conversion layer 48G that emits green light. The blue light-emitting region LAB is a blue PL emission region and includes a blue wavelength conversion layer 48B that emits blue light. In other words, the wavelength conversion layer 48 includes the red light-emitting region LAR that emits red light, the green light-emitting region LAG that emits green light, and the blue light-emitting region LAB that emits blue light, as a plurality of PL emission regions having different luminescent colors.

The bank 14 according to the present embodiment has the same configuration as the bank 14 according to each of the embodiments described above. For example, the bank 14 according to the present embodiment is formed at positions straddling boundaries between the subpixels adjacent to each other in a plan view. Also in the present embodiment, a region on the bank 14 is a non-light-emitting region NLA, which is a region not intended for PL emission. The bank 14 according to the present embodiment is made of the same material as the material for the bank 14 according to each of the embodiments described above.

At least one wavelength conversion layer in the display device 44 includes a main region and an outer edge region formed at an outer edge of the wavelength conversion layer. The main region is a region capable of exhibiting a wavelength conversion function, which is a main function of the wavelength conversion layer. For example, the red wavelength conversion layer 48R is formed in a light-emitting region that mainly emits red light by absorbing light. The main region may also be formed in the non-light-emitting region NLA. The outer edge region is a region formed at an outer edge of the wavelength conversion layer and is made of an outer edge material that is a material different from the main luminescent material used for the main region. The non-light-emitting region NLA of the wavelength conversion layer 48, including a first outer edge region, includes this first outer edge region at a position overlapping the bank 14 in a plan view.

The red light-emitting region LAR of the wavelength conversion layer 48 according to the present embodiment has the same configuration as the red light-emitting region LAR of the light-emitting layer 10 according to any one of the embodiments described above, except that the red wavelength conversion layer 48R is provided instead of the red light-emitting layer 10R. For example, similar to the red light-emitting layer 10R according to any one of the embodiments described above, the red wavelength conversion layer 48R includes a red main region 15R and a red first outer edge region 16R adjacent to a side surface 10RS of an edge on a green light-emitting layer 10G side.

For example, the red main region 15R contains, as a main luminescent material, red quantum dots 18R described above and red main ligands 20R that are coordinated to the red quantum dots 18R. For example, the red first outer edge region 16R according to the present embodiment contains, as a first outer edge material, red first quantum dots 26R and red first outer edge ligands 28R that are coordinated to the red first quantum dots 26R.

The green light-emitting region LAG of the wavelength conversion layer 48 according to the present embodiment has the same configuration as the green light-emitting region LAG of the light-emitting layer 10 according to any one of the embodiments described above, except that the green wavelength conversion layer 48G is provided instead of the green light-emitting layer 10G. For example, similar to the green light-emitting layer 10G according to any one of the embodiments described above, the green wavelength conversion layer 48G includes a green main region 15G and a green first outer edge region 16G adjacent to a side surface 10GS of an edge on a green light-emitting layer 10G side.

For example, the green main region 15G contains, as a main luminescent material, green quantum dots described above and green main ligands 20G that are coordinated to the green quantum dots. For example, the green first outer edge region 16G according to the present embodiment contains, as a first outer edge material, green first quantum dots and green first outer edge ligands that are coordinated to the green first quantum dots.

The blue light-emitting region LAB of the wavelength conversion layer 48 according to the present embodiment has the same configuration as the blue light-emitting region LAB of the light-emitting layer 10 according to any one of the embodiments described above, except that the blue wavelength conversion layer 48B is provided instead of the blue light-emitting layer 10B. The blue wavelength conversion layer 48B contains the same main luminescent material as the blue light-emitting layer 10B according to any of the embodiments described above.

In the present embodiment, the light source unit 46 may irradiate light-emitting regions of the wavelength conversion layer 48 with light individually. For example, the light source unit 46 may include light-emitting elements, each emitting ultraviolet light for each subpixel, and the light emitting elements may be controlled on a subpixel-by-subpixel basis. Alternatively, the light source unit 46 may include a backlight unit that emits ultraviolet light and a liquid crystal element that is formed on the backlight unit and controls amounts of light from the backlight unit to the wavelength conversion layer on a subpixel-by-subpixel basis.

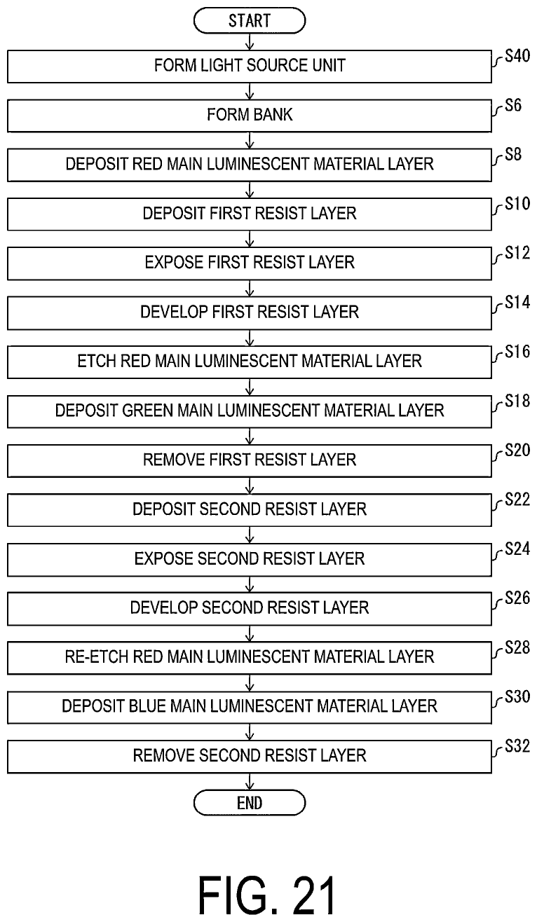

In each of the wavelength conversion layers of the wavelength conversion layer 48 according to the present embodiment, the outer edge region is formed as the non-light-emitting region located at the outer edge of each of the wavelength conversion layers of the wavelength conversion layer 48. The outer edge region has lower luminous efficiency than the main region or does not emit light. With the above configuration, the display device 44 according to the present embodiment can suppress occurrence of color blurring, color mixing, or the like for the same reason as described in the first embodiment. A method for manufacturing the display device 44 according to the present embodiment will be described with reference to FIG. 21. FIG. 21 is a flowchart for describing the method for manufacturing the display device 44 according to the present embodiment.

In the method for manufacturing the display device 44 according to the present embodiment, first, the light source unit 46 is formed (step S40). The light source unit 46 may be formed by forming a light-emitting element that emits ultraviolet light to match positions where the respective subpixels of the display device 44 are formed, using a known method. Alternatively, the light source unit 46 may be formed by forming a liquid crystal element on a backlight unit that emits ultraviolet light to match positions where the respective subpixels of the display device 44 are formed, using a known method.

In the method for manufacturing the display device 44 according to the present embodiment, the bank 14 is formed (step S6) following the formation of the light source unit 46. The bank 14 according to the present embodiment is made of the same material and formed at the same position as the bank 14 according to each of the embodiments described above. Therefore, the bank 14 according to the present embodiment can be manufactured using the same method as in step S6 according to each of the embodiments described above.

Subsequently, the wavelength conversion layer 48 is manufactured. Here, as described above, the wavelength conversion layer 48 according to the present embodiment has the same configuration as the light-emitting layer 10 according to each of the embodiments described above. Therefore, the wavelength conversion layer 48 according to the present embodiment can be manufactured by the same method as the method for forming the light-emitting layer 10 according to each of the embodiments described above. For example, as illustrated in FIG. 21, the wavelength conversion layer 48 according to the present embodiment can be formed by sequentially performing steps S8 through S32 in the method for manufacturing the display device 2 according to the first embodiment by substituting the light-emitting layer 10 with the wavelength conversion layer 48, following step S6. Thus, the manufacturing of the display device 44 according to the present embodiment is completed.

As described above, the wavelength conversion layer 48 in the present embodiment can be manufactured by the same method as the method for manufacturing the light-emitting layer 10 according to each of the embodiments described above. Therefore, also in the present embodiment, the red light-emitting region LAR can be formed in an etching step using a resist layer used for patterning other light-emitting regions. Thus, according to the method for manufacturing the display device 44 according to the present embodiment, the number of required steps can be reduced.

According to the above manufacturing method, as described above, the wavelength conversion layers of the wavelength conversion layer 48 according to the present embodiment are formed in contact with each other in the subpixels adjacent to each other.

For example, the display device 44 according to the present embodiment may include the bank 14 made of a transparent material or may not include the bank 14. Here, as described above, according to the method for manufacturing the display device 44 according to the present embodiment, spaces between the light-emitting regions of the wavelength conversion layer 48 adjacent to each other can be reduced. This reduces possibility that, between the subpixels, light from the light source unit 46 is transmitted between the light-emitting regions of the wavelength conversion layer 48 and is extracted without being converted by the wavelength conversion layer 48.

### Fifth Embodiment

### Scattering Material Layer

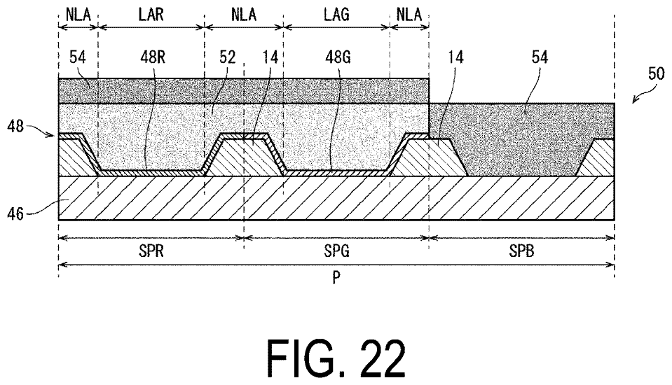

FIG. 22 is a schematic cross-sectional view of a display device 50 according to the present embodiment. In particular, FIG. 22 illustrates a cross section at a position corresponding to the cross section of the display device 44 according to the previous embodiment illustrated in FIG. 20.

The display device 50 according to the present embodiment is different from the display device 44 according to the previous embodiment in that a wavelength conversion layer 48 does not include a blue wavelength conversion layer 48B but only includes a red wavelength conversion layer 48R and a green wavelength conversion layer 48G. For example, the red wavelength conversion layer 48R according to the present embodiment includes a red main region 15R and a red first outer edge region 16R formed at an edge of the red main region 15R. One of the red wavelength conversion layer 48R and the green wavelength conversion layer 48G according to the present embodiment may include only the main region.

The display device 50 according to the present embodiment also includes a transparent resist layer 52 on the red wavelength conversion layer 48R and the green wavelength conversion layer 48G of the wavelength conversion layer 48. The transparent resist layer 52 transmits light from each of the red wavelength conversion layer 48R and the green wavelength conversion layer 48G. The transparent resist layer 52 may contain the same material as the material contained in any one of the first resist layer 38, the second resist layer 40, and the third resist layer 42 in each of the embodiments described above as long as the material is a transparent material.

In the present embodiment, a light source unit 46 emits blue light. Light emitted by the light source unit 46 may be, for example, the same light as the blue light emitted by the light-emitting layer 10 or the blue wavelength conversion layer 48B according to the corresponding embodiment of the embodiments described above. For example, the light source unit 46 may include individually driven blue light-emitting elements on a subpixel-by-subpixel basis.

Thus, in the display device 50 according to the present embodiment, in a red subpixel SPR and a green subpixel SPG, a red light-emitting region LAR and a green light-emitting region LAG absorb blue light from the light source unit 46 and emit red light and green light, respectively. On the other hand, in a blue subpixel SPB, blue light from the light source unit 46 is extracted as it is.

The transparent resist layer 52 may absorb blue light from the light source unit 46. For example, in the red subpixel SPR and the green subpixel SPG, blue light from the light source unit 46 may be transmitted through the wavelength conversion layer 48 without being converted in the wavelength conversion layer 48. Here, when the transparent resist layer 52 absorbs blue light from the light source unit 46, the blue light from the light source unit 46 transmitted through the wavelength conversion layer 48 is absorbed by the transparent resist layer 52. Therefore, with the above configuration, in the red subpixel SPR and the green subpixel SPG, extraction of blue light from the light source unit 46 transmitted through the wavelength conversion layer 48 is reduced.

Furthermore, the display device 50 according to the present embodiment includes a scattering material layer 54. The scattering material layer 54 is a layer containing a scattering material that scatters light from the light source unit 46 and the wavelength conversion layer 48. Therefore, in the red subpixel SPR and the green subpixel SPG, red light and green light from the red light-emitting region LAR and the green light-emitting region LAG are scattered by the scattering material layer 54 and extracted, respectively. In the blue subpixel SPB, blue light from the light source unit 46 is scattered by the scattering material layer 54, and the scattered light is extracted. A scattering material contained in the scattering material layer 54 is not limited in type as long as the scattering material scatters light from the light source unit 46 and the wavelength conversion layer 48. For example, a known scattering material can be employed.

Except for the above points, the display device 50 according to the present embodiment has the same configuration as the display device 44 according to the previous embodiment. Therefore, in each of the wavelength conversion layers of the wavelength conversion layer 48 according to the present embodiment, an outer edge region is formed as a non-light-emitting region located at the outer edge of each of the wavelength conversion layers of the wavelength conversion layer 48. The outer edge region has lower luminous efficiency than the main region or does not emit light. Thus, the display device 50 according to the present embodiment can suppress occurrence of color blurring, color mixing, or the like for the same reason as described in the first embodiment.

In the present embodiment, light from the wavelength conversion layer 48 in the red subpixel SPR, light from the wavelength conversion layer 48 in the green subpixel SPG, and light from the light source unit 46 in the blue subpixel SPB are all scattered in the scattering material layer 54. Accordingly, viewing angle dependence of light obtained from each subpixel can be reduced, and thus a viewing angle of the display device 50 can be further increased.

In particular, in the present embodiment, for example, it is assumed that light from each of the red light-emitting region LAR and the green light-emitting region LAG is light from quantum dots contained therein, and light from the light source unit 46 is light from a blue light emitting diode. In this case, before being scattered in the scattering material layer 54, the light from the light source unit 46 tends to have higher viewing angle dependence than the light from each of the red light-emitting region LAR and the green light-emitting region LAG. According to the above configuration, the scattering material layer 54 reduces a difference in viewing angle dependence between the light from each of the red light-emitting region LAR and the green light-emitting region LAG and the light from the light source unit 46, thereby improving display quality of the display device 50.

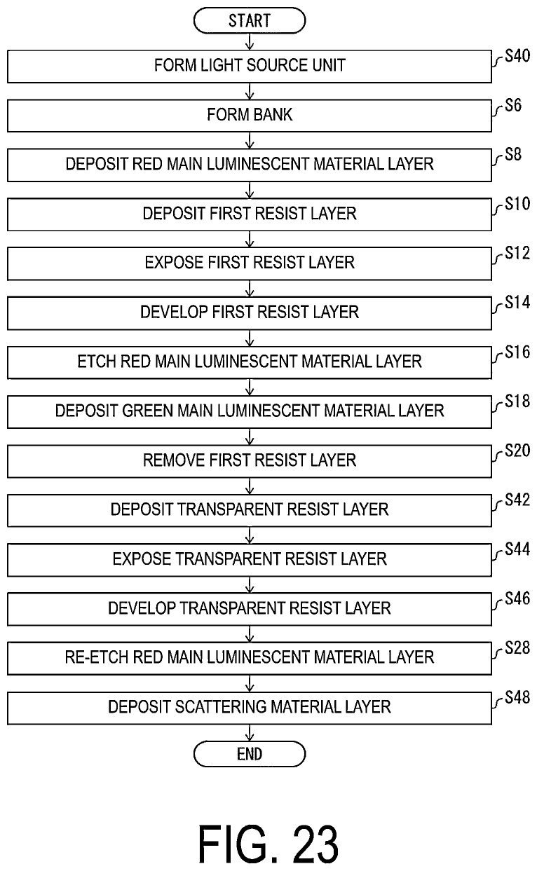

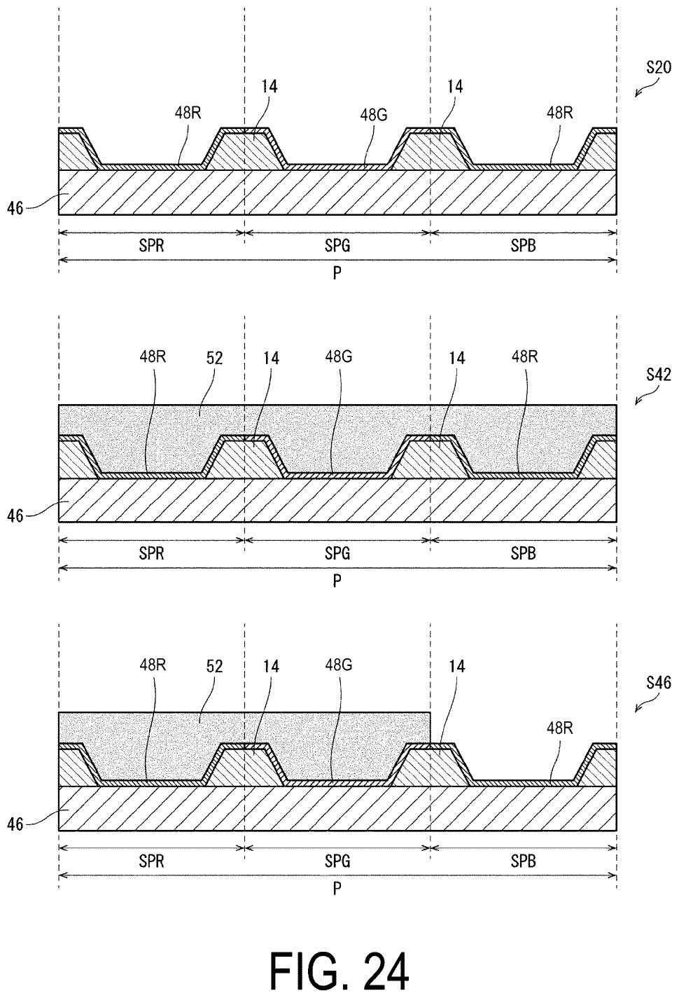

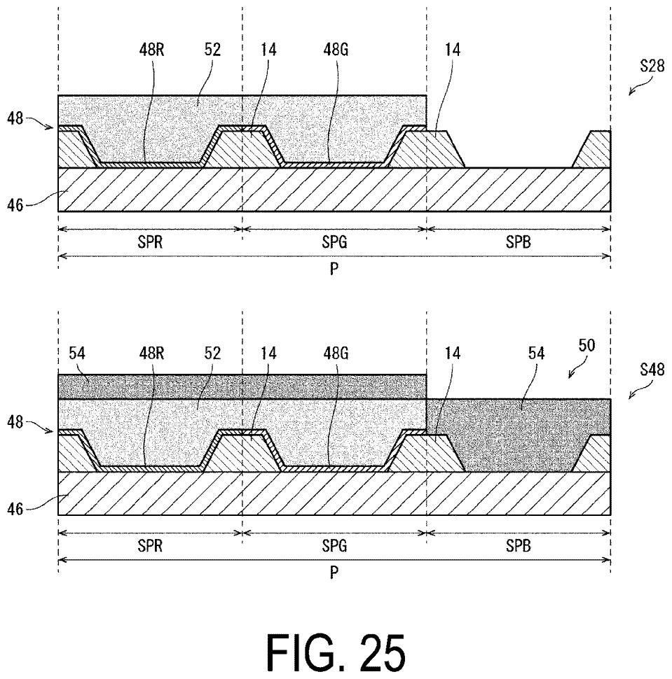

A method for manufacturing the display device 50 according to the present embodiment will be described with reference to FIG. 23 to FIG. 25. FIG. 23 is a flowchart for describing the method for manufacturing the display device 50 according to the present embodiment. FIG. 24 and FIG. 25 are cross-sectional views illustrating steps of the display device 50 in some steps of the method for manufacturing the display device 50 according to the present embodiment.

Part of the method for manufacturing the display device 50 according to the present embodiment is the same as part of the method for manufacturing the display device 44 according to the previous embodiment. For example, in the method for manufacturing the display device 50 according to the present embodiment, steps S40 through S20 illustrated in FIG. 21 in the method for manufacturing the display device 44 according to the previous embodiment are sequentially performed. Thus, a structure illustrated in step S20 in FIG. 24 is obtained.

Subsequently, the transparent resist layer 52 is deposited on the red wavelength conversion layer 48R and the green wavelength conversion layer 48G (step S42). Deposition of the transparent resist layer 52 may be performed using the same method as the deposition of any one of the first resist layer 38, the second resist layer 40, and the third resist layer 42 in each of the embodiments described above.

Subsequently, the transparent resist layer 52 is exposed (step S44). Exposure of the transparent resist layer 52 may be performed, for example, by exposing the transparent resist layer 52 using the same method as in the second exposure step in the method for manufacturing the display device 2 according to the first embodiment.

Subsequently, the transparent resist layer 52 is developed (step S46). Development of the transparent resist layer 52 may be performed, for example, by developing the transparent resist layer 52 using the same method as in the second development step in the method for manufacturing the display device 2 according to the first embodiment.

In the present embodiment, only the transparent resist layer 52 formed at a position overlapping the blue subpixel SPB is removed in step S46. Thus, at the time of completion of step S46, the red wavelength conversion layer 48R is exposed at the position overlapping the blue subpixel SPB.

Subsequently, using the same method as in the second etching step (step S28) in the method for manufacturing the display device 2 according to the first embodiment, a portion of the red wavelength conversion layer 48R is etched from a surface on a side of the transparent resist layer 52. An etching solution used in the etching may have the same configuration as the first etching solution or the second etching solution in each of the embodiments described above. By this etching, only the red wavelength conversion layer 48R exposed from the transparent resist layer 52 is removed at the position overlapping the blue subpixel SPB.

Subsequently, the scattering material layer 54 is deposited by applying a material containing the scattering material (step S48). A method for applying the scattering material layer 54 is not limited as long as a thin film of the scattering material contained in the scattering material layer 54 can be deposited in common to all the subpixels, and any known application method may be employed. Thus, the display device 50 illustrated in FIG. 25 can be manufactured.

Also in the present embodiment, the red light-emitting region LAR can be formed in the etching step using the resist layer used for patterning the other light-emitting regions. Thus, according to the method for manufacturing the display device 50 according to the present embodiment, the number of required steps can be reduced.

According to the above manufacturing method, as described above, the red light-emitting region LAR and the green light-emitting region LAG are brought into close contact with each other, and space between the red light-emitting region LAR and the green light-emitting region LAG can be reduced. For the same reason, according to the above manufacturing method, the green light-emitting region LAG and the scattering material layer 54 in the blue subpixel SPB are brought into close contact with each other, and space between the green light-emitting region LAG and the scattering material layer 54 in the blue subpixel SPB can be reduced.

For example, the display device 50 according to the present embodiment may include the bank 14 made of a transparent material or may not include the bank 14. Here, as described above, according to the method for manufacturing the display device 50 according to the present embodiment, spaces between the adjacent light-emitting regions in the wavelength conversion layer 48 and between the wavelength conversion layer 48 and the scattering material layer 54 can be reduced. This reduces possibility that, between the subpixels, light from the light source unit 46 is transmitted between the light-emitting regions of the wavelength conversion layer 48 and between the light-emitting region and the scattering material layer 54 and extracted.

### Sixth Embodiment

### Modified Example of Display Device Including Wavelength Conversion Layer

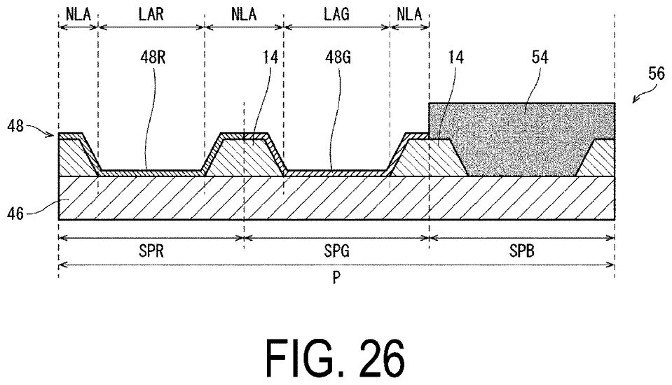

FIG. 26 is a schematic cross-sectional view of a display device 56 according to the present embodiment. In particular, FIG. 26 illustrates a cross section at a position corresponding to the cross section of the display device 50 according to the previous embodiment illustrated in FIG. 22.

The display device 56 according to the present embodiment is different from the display device 50 according to the previous embodiment only in that a transparent resist layer 52 and a scattering material layer 54 are not provided in either a red subpixel SPR or a green subpixel SPG. In other words, the display device 56 according to the present embodiment does not include the transparent resist layer 52 and includes the scattering material layer 54 only in a blue subpixel SPB.

Except for the above points, the display device 56 according to the present embodiment has the same configuration as the display device 50 according to the previous embodiment. Therefore, in each of the wavelength conversion layers of a wavelength conversion layer 48 according to the present embodiment, an outer edge region is formed as a non-light-emitting region located at an outer edge of each of the wavelength conversion layers of the wavelength conversion layer 48. The outer edge region has lower luminous efficiency than the main region or does not emit light. Thus, the display device 56 according to the present embodiment can suppress occurrence of color blurring, color mixing, or the like for the same reason as described in the first embodiment.

When the wavelength conversion layer 48 contains quantum dots as a main luminescent material in each main region, light emitted by the quantum dots absorbing light from the light source unit 46 is light scattered to some extent by the quantum dots. Therefore, in order to reduce viewing angle dependence of light obtained from each subpixel, it is effective to scatter light from the blue subpixel SPB. The display device 56 according to the present embodiment scatters light from the light source unit 46 in the scattering material layer 54 only in the blue subpixel SPB. Therefore, the display device 56 more efficiently reduces a difference between the viewing angle dependence of light obtained from each of the red subpixel SPR and the green subpixel SPG and the viewing angle dependence of light obtained from the blue subpixel SPB, thereby improving display quality.

The display device 56 according to the present embodiment is obtained by removing the scattering material layer 54 in the red subpixel SPR and the green subpixel SPG together with the transparent resist layer 52 by peeling off the transparent resist layer 52 from the display device 50 according to the previous embodiment. Peeling off of the transparent resist layer 52 may be performed using the same method as the peeling off of any one of the first resist layer 38, the second resist layer 40, and the third resist layer 42 in each of the embodiments described above.

In other words, in the present embodiment, the wavelength conversion layer 48 can be manufactured using the same method as the method for manufacturing the wavelength conversion layer 48 according to the previous embodiment. Therefore, also in the present embodiment, a red light-emitting region LAR can be formed in an etching step using a resist layer used for patterning other light-emitting regions. Thus, according to the method for manufacturing the display device 56 according to the present embodiment, the number of required steps can be reduced.

The disclosure is not limited to the embodiments described above, and various modifications may be made within the scope of the claims. Embodiments obtained by appropriately combining technical approaches disclosed in the different embodiments also fall within the technical scope of the disclosure. Furthermore, novel technical features can be formed by combining the technical approaches disclosed in each of the embodiments.

1. A display device comprising:
a light-emitting layer,
wherein the light-emitting layer includes a light-emitting region configured to emit light of a predetermined color and a non-light-emitting region different from the light-emitting region and formed in a region including an outer edge of the light-emitting layer, and
the non-light-emitting region includes a first outer edge region containing a first outer edge material different from a main luminescent material constituting the light-emitting region at the outer edge of the light-emitting layer.

2. (canceled)

3. The display device according to claim 1 comprising:
n types of the light-emitting layers having different luminescent colors from each other, where n is a natural number of 2 or more,
wherein only one type of the light-emitting layer includes the light-emitting region and the first outer edge region.

4. (canceled)

5. The display device according to claim 1,
wherein the main luminescent material includes main quantum dots and main ligands,
the first outer edge material includes first quantum dots and first outer edge ligands, and
a density of the first outer edge ligands in the first outer edge region is lower than a density of the main ligands in the light-emitting region.

6. The display device according to claim 1,
wherein the main luminescent material includes main quantum dots and main ligands,
the first outer edge material includes first quantum dots and first outer edge ligands, and
the first quantum dots are oxides of the main quantum dots.

7. The display device according to claim 1,
wherein the main luminescent material includes main quantum dots and main ligands, each of the main quantum dots having a main shell, and
the first outer edge material includes first quantum dots and first outer edge ligands, each of the first quantum dots having a first shell that is thinner than the main shell.

8. The display device according to claim 5,
wherein in the main luminescent material and the first outer edge material, at least the main ligands and the first outer edge ligands are different from each other.

9. The display device according to claim 8,
wherein a diameter of a core of each of the main quantum dots is substantially identical to a diameter of a core of each of the first quantum dots.

10. The display device according to claim 8,
wherein the first outer edge ligands have water absorbing properties.

11. The display device according to claim 10,
wherein each of the first outer edge ligands includes at least one selected from the group consisting of tetramethylammonium hydroxide, 2-aminoethanethiol hydrochloride, 2-methaneaminoethanethiol hydrochloride, 2-ethanaminoethanethiol hydrochloric acid, 2-dimethylaminoethanethiol hydrochloride, 2-methylethylaminoethanethiol hydrochloride, and 2-diethylaminoethanethiol hydrochloride.

12. The display device according to claim 8,
wherein the first outer edge ligands have water repellency.

13. The display device according to claim 12,
wherein each of the first outer edge ligands is a ligand including at least one coordinating functional group selected from the group consisting of a thiol group, an amino group, a carboxyl group, a phosphonic group, a phosphine group, and a phosphine oxide group.

14-15. (canceled)

16. The display device according to claim 1,
wherein at least one of the light-emitting layers further includes a second outer edge region adjacent to at least one side surface of the first outer edge region on a side opposite to the light-emitting region and having a second outer edge material different from both the main luminescent material and the first outer edge material.

17-22. (canceled)

23. A method for manufacturing a display device comprising:
depositing a first main luminescent material layer containing a first main luminescent material;
depositing a first resist layer on the first main luminescent material layer;
exposing the first resist layer;
removing a portion of the first resist layer by developing the first resist layer;
etching a portion of the first main luminescent material layer from a surface on a side of the first resist layer;
forming a first outer edge region adjacent to at least one side surface of the first main luminescent material layer and containing a first outer edge material different from the first main luminescent material; and
depositing a second main luminescent material layer containing a second main luminescent material having a different luminescent color from a luminescent color of the first main luminescent material.

24. The method for manufacturing a display device according to claim 23, further comprising:
after the depositing a second main luminescent material layer, peeling off the first resist layer remaining.

25. The method for manufacturing a display device according to claim 23,
wherein the etching a portion of the first main luminescent material layer and the forming a first outer edge region are performed simultaneously.

26. The method for manufacturing a display device according to claim 23,
wherein the first main luminescent material includes first main quantum dots and first main ligands, and
in the forming a first outer edge region, the first outer edge region is formed by substituting at least some of the first main ligands of the first main luminescent material with first outer edge ligands by a first outer edge region material including the first outer edge ligands different from the first main ligands.

27. The method for manufacturing a display device according to claim 26,
wherein in the etching a portion of the first main luminescent material layer, etching is performed using a first etching solution, and
the first etching solution is a solution containing, in a solvent, a solute containing at least one selected from the group consisting of tetramethylammonium hydroxide, 2-aminoethanethiol hydrochloride, 2-methanaminoethanethiol hydrochloride, 2-ethanaminoethanethiol hydrochloric acid, 2-dimethylaminoethanethiol hydrochloride, 2-methylethylaminoethanethiol hydrochloride, and 2-diethylaminoethanethiol hydrochloride.

28-29. (canceled)

30. The method for manufacturing a display device according to claim 26,
wherein in the etching a portion of the first main luminescent material layer, etching is performed using a first etching solution, and
the first etching solution is a solution containing molecules in a solvent, the molecules including at least one selected from the group consisting of a thiol group, an amino group, a carboxyl group, a phosphonic group, a phosphine group, and a phosphine oxide group as a functional group and being dispersible in etching solutions.

31-32. (canceled)

33. The method for manufacturing a display device according to claim 23,
wherein in the etching a portion of the first main luminescent material layer, etching is performed using a first etching solution, and
the first etching solution is an acid aqueous solution.

34-35. (canceled)

36. The method for manufacturing a display device according to claim 23, further comprising:
depositing a second resist layer on the first main luminescent material layer and the second main luminescent material layer;
removing a portion of the second resist layer by exposing and developing the second resist layer;
etching a portion of the second main luminescent material layer from a surface on a side of the second resist layer;
forming a second outer edge region adjacent to at least one side surface of the second main luminescent material layer and containing a second outer edge material different from the second main luminescent material; and
depositing a third main luminescent material layer containing a third main luminescent material having a different luminescent color from the luminescent colors of both the first main luminescent material and the second main luminescent material.
